(19) United States
(12) Patent Application Publication
(10) Pub. No.: US 2025/0311578 A1
(43) Pub. Date: Oct. 2, 2025

(54) SEGMENTED OLED WITH ELECTROSTATIC DISCHARGE PROTECTION

(71) Applicant: OLEDWorks LLC, Rochester, NY (US)

(72) Inventors: Michael BOROSON, Pittsford, NY (US); Bruno Primerano, Honeoye Falls, NY (US); Kathleen M. Vaeth, Penfield, NY (US); Jörg Knipping, Wegberg (DE); Michel Büchel, Aachen (DE); Juergen Eser, Juelich (DE)

(21) Appl. No.: 18/864,410

(22) PCT Filed: May 16, 2022
(86) PCT No.: PCT/US2022/029413

§ 371 Date: Nov. 8, 2024

(51) Int. Cl. H10K 59/19; H10K 59/126; H10K 59/131; H10K 102/00

(52) U.S. Cl. CPC H10K 59/19; H10K 59/126; H10K 59/131; H10K 2102/3023

(57) ABSTRACT

A segmented bottom-emitting OLED device compromising an array of multiple OLED segments arranged on a common transparent substrate, where the array forms an emitting area where each segment is separated by a non-emitting gap; wherein each OLED segment is defined by a transparent bottom electrode segment, organic layers for light emission, and a top electrode; wherein between the bottom electrode and the substrate in at least one OLED segment, there is a transparent insulating layer that is closer to the bottom electrode segment and a transparent conductive layer that is closer to the substrate.

### CROSS REFERENCE TO RELATED APPLICATIONS

Reference is made to co-filed and co-assigned PCT application PCT/US22/XXXXX entitled “SEGMENTED OLED” under Attorney Docket OLWK-0024-PCT which claims the benefit of U.S. Provisional Application No. 63/192,942 filed May 25, 2021 under Attorney Docket OLWK-0024-USP.

### BACKGROUND

Electrostatic discharge (ESD) is a sudden and momentary flow of electric current between two electrically charged objects. ESD can cause harmful effects of importance in industry, including failure of electronic components. These can suffer permanent damage when subjected to high voltages. For OLED devices, the sensitivity to ESD can depend on the kinds of organic materials used for light emission; some materials and formulations can be more sensitive than others. Sensitive electronic components need to be protected during and after manufacture, during shipping/handling and device assembly, and in the finished device. ESD is often a particular problem when the device is in an “OFF” or a non-operational state.

Some general methods of providing ESD protection in OLED devices include: ESD protection as part of driving circuit (for example, see U.S. Pat. No. 10,692,957B2); adding peripherical conductive structures (for example, see U.S. Pat. No. 7,944,140B2); adding a separate ESD protection circuit (for example, see U.S. Pat. No. 9,246,121B2); and using a capacitor or transistor outside the emitting area (for example, see U.S. Pat. No. 6,046,547A). Such methods may or may not be useful when the device is in an “OFF” state. Due to the dielectric nature of electronics component and assemblies, electrostatic charging cannot be completely prevented during handling of devices. An efficient way to prevent ESD is to use materials that are not too conductive but will slowly conduct or bleed static charges away. Such dissipative materials typically will have resistivity values below 10¹² ohm-meters. Such materials are able to conduct electricity, but do so very slowly. Any built-up static charges can then dissipate without the sudden discharge that can harm the internal structure of the electronic device.

Not all electronic devices are equally sensitive to ESD damage. It can be dependent on the application or environment involved. For example, an electronic component assembled into a sealed module under controlled conditions may not be prone to ESD damage, whereas the same electronic component may be sensitive if manually handled. Moreover, there are levels of ESD; an electronic component may be robust against a lower level of ESD, but sensitive at higher levels. For some applications (i.e., automotive), devices may be exposed to ESD in the range of 8 kV or less. However, ESD voltages can be as high as 30 kV.

One way to prevent or suppress ESD would be by incorporating a capacitor in the device. For example, see https://www.vishay.com/docs/45257/vishayautomlccsesdprotect.pdf. Typically, the capacitor is integral to or located close to the ESD sensitive components in order to absorb and then level out or dissipate the unwanted voltage spikes.

OLEDs, being constructed of two area electrodes separated by organic layers that are resistive, are a type of capacitor. Like any capacitor, their inherent capacitance is dependent on the area of overlap between the two electrodes, the distance between the electrodes, the resistivity of the organic layers, and the type of materials used among other factors.

Ideally, if the inherent capacitance of the OLED is sufficiently high, it should be able to dissipate any ESD without damage to the OLED or its associated circuitry. However, since the inherent capacitance is dependent on the area size of the OLED among other factors, large format OLED devices (for example, OLEDs for general lighting applications which typically have an area of greater than 25 cm²) could have high enough inherent capacitance to be relatively insensitive to ESD damage. ESD protection may not be needed. Very small format OLED devices (for example, the pixels in active- and passive-matrix OLED displays which typically have an area of approximately 200-300 μ² at most) have relatively low inherent capacitance and can be very sensitive to ESD damage. However, since OLED displays already use complicated control and drive circuitry, it is relatively straightforward to add external ESD protection as part of the circuitry.

OLED devices that are between these extremes in size can be sensitive to ESD damage since their inherent capacitances are not large enough to effectively dissipate ESD and often have simple (and typically off-substrate) control circuitry for which adding additional ESD protection circuitry would be problematic from a cost and ease of manufacture viewpoint. Typically, OLEDs less than 1 cm² in area, and especially 0.5 cm² or less, might be particularly suspectable to ESD damage without expensive or complicated external protection mechanisms.

For some applications, multiple independently controlled individual OLED devices of this intermediate size range can be mounted on a single substrate to provide a ‘tiled’ device. In a “tiled” OLED device, each independent OLED light source is previously and independently manufactured in its entirely (except for electrical connections) including its own substrate and mounted side-by-side or in an array. “Tiled” devices can be expensive to manufacture because of the complicated assembly required.

For other applications, multiple independently controlled individual OLED devices can be manufactured directly on a single common substrate to provide a “segmented” OLED device. In particular, a segmented OLED has each independent OLED segment manufactured directly in its entirely side-by-side or in an array on the same substrate. There are non-emitting gaps or spaces between the individual segments. Such segmented OLED light sources can offer manufacturing and cost advantages because many layers can be shared across all the individual units and there is no need to handle or mount the separate OLED panels.

A segmented OLED device can provide either variable general lighting (i.e., by supplying power to the individual segments according to desired amount of overall light) or a low-resolution communication device (i.e., by supplying power to the segments in a pattern). However, in a segmented OLED device, individual OLED segments are significantly larger than the OLED pixels in a high-resolution display. OLED segments will have a minimum size of at least 0.025 cm² and more preferably, 0.05 cm² or greater. This is by design since larger OLEDs will produce more light for applications where high resolution is not needed. Moreover, while OLED pixels in displays require complicated on-substrate drive circuitry to be operated at high frequency, segmented OLED devices, which operate at low frequency, can use simpler off-substrate drive circuitry which lowers manufacturing cost and complexity.

Segmented OLED devices are particularly suitable for automobile exterior lighting applications (e.g., tail-lights) since they, unlike LED devices, require no additional reflectors, light guides, or additional optics to generate homogeneous surface light. For example, see M. Kruppa et al, Information Display 4/19, p. 14-18 (2019); H. Bechert et al, “Flexible and highly segmented OLED for automotive applications”, Proc. SPIE 10687, Organic Electronics and Photonics: Fundamentals and Devices, 106870Q (21 May 2018); M. Kondakova et al, 8-1: Invited Paper: Development of High-Temperature Stable Red OLEDs for Automotive Lighting. SID Symposium Digest of Technical Papers, 51:83-85 (2020); C. May, “Flexible OLED lighting and signage for automotive application,” 2021 28th International Workshop on Active-Matrix Flatpanel Displays and Devices (AM-FPD), 2021, pp. 42-45; and D. Q. Chowdhury et al, “Application of OLED for Automotive Lighting,” 2019 26th International Workshop on Active-Matrix Flatpanel Displays and Devices (AM-FPD), 2019, pp. 1-3.

Applications such as automobile tail-lights often require some degree of visibility from the side as well as directly from the rear so the tail-light assembly often has a complex design with a mixture of curved and relatively flat surfaces. Segmented OLED devices can be prepared on flexible substrates which simplifies design considerations in a non-planar tail-light assembly. However, automobile tail-light assemblies are an integral part of the overall exterior appearance of the vehicle and must provide a sleek and compatible design and appearance.

In general, OLED devices are formed on a substrate and can be either top-emitting (light emission from the surface opposite the substrate) or bottom-emitting (light emission through a transparent substrate). In order to create an individually controlled OLED segment, at least one of the electrodes must be divided into segments; that is, the electrode for one OLED segment is electrically separated from a corresponding electrode in a different OLED segment. In this way, the emission from each of the OLED segments can be individually controlled by a single unique electrical power feed (also referred to as bus line, bus bar, metal trace, conductive trace, lead or current trace) to the electrode segment.

The power leads are desirably formed directly on the substrate before any of the organic OLED layers are applied. This is because they must be individually patterned since there is at least one power lead for each segment. One cost-effective way to manufacture the power leads is to use photolithographic processes and techniques that are capable of forming very fine patterns of conductive structures. However, photolithography is generally not compatible when used over organic OLED layers. Fine metal masking processes and techniques can be used to create the power lines, even over organic OLED layers, but it would be more expensive and more prone to defects during manufacture. The conductive structures created by masking processes are also significantly larger than those that can be made using photolithography.

For bottom-emitting OLED with bottom segmented electrodes, the individual power feed that connect to each electrode segment is desirably located at the same (horizontal) level or below (between the electrode segment and the substrate) as the electrode segment. However, any chosen location is a matter of trade-offs. The power feeds can be located laterally adjacent to the electrode segments (separated by an insulating material to maintain non-contact) but this can undesirably increase the space between electrode segments (due to the number of individual power feeds required) as well as being prone to shorting between the power feed of one electrode segment and a second electrode segment. The power feeds can be located below the electrode segments, but must be electrically isolated from the overlying electrode segments in order to avoid shorting. This can complicate manufacturing since additional layers are required. If the power feeds are located in the emission pathway, they may be visible which would be undesirable.

Although both top-emitting and bottom-emitting OLEDs are suitable for automobile applications, bottom-emitting OLEDs are preferred for at least two reasons. First, robust encapsulation is necessary for exterior applications. This is more difficult to achieve with transparent encapsulation, particularly for flexible OLEDs, which is required for a top-emitting OLED. A bottom-emitting OLED can use very robust encapsulation since the encapsulation on the non-emitting side does not need to be transparent. Second, the OLED will be located in a confined space where heat build-up can be problematic. A bottom-emitting OLED allows for a heat sink to be located on the back side. With a top-emitting OLED, the heat sink is located on the opposite side of the substrate which reduces the rate of heat transfer and so, cooling is not as efficient.

However, since at least some OLED segments in a segmented device may be small enough to be sensitive to ESD damage where such small OLED segments may only have simple direct electrical connections to off-substrate control circuitry, there exists a need to provide ESD protection which is simple to manufacture at a low cost. The ESD protection should be on-substrate and passive (i.e., not requiring a power source) because the protection is needed when the OLED device is not in operation or powered (“OFF”) nor even attached to any other component.

H. Bechert et al, “Thin-Film Electrostatic Discharge Protection for Highly Segmented OLEDs in Automotive Applications”, Adv. Mater. Technol., 4, 1800696 (2019), along with an analogous communication in Adv. Mater. Technol., describes a top-emitting segmented OLED device where electrostatic protection is provided by an on-substrate passive capacitor of a continuous and opaque conductive layer (composed of Cr/Al/Cr, which is opaque) as one electrode, an insulating layer (composed of Al₂O₃ or ZrO₂), and the anode segments (composition not disclosed) as the opposite electrode. The continuous conductive layer, which is located under all electrode segments, is not connected to anything. Because the conductive layer is composed of conductive metal, it is not suitable for a bottom-emitting device. Moreover, the opaque conductive layer lies beneath all electrode segments. Such an arrangement can also be susceptible to shorting between electrode segments because of manufacturing defects, particularly due to pinholes in the insulating layer. This reference does not disclose the location of the power feeds which is an important consideration.

U.S. Pat. No. 8,445,910 describes a bottom-emitting OLED display where the driving circuitry for each pixel contains a storage capacitor, which has the structure of transparent anode/insulating layer/transparent conductive layer, located in the emission path. This reference describes the transparent conducting layer as being patterned either as a wiring line or only under the anode. However, if the transparent conducting layer (the lower electrode of the capacitor) was part of a wiring line, such a device would not be operable since the transparent capacitor is part of the driving circuit for that pixel and so, the transparent conducting layer cannot be connected to any other pixel in the display. U.S. Pat. No. 10,825,883B2 also describes a bottom-emitting OLED display where the driving circuitry for each pixel contains a storage capacitor which has the structure of transparent anode/insulating layer/transparent conductive layer. This reference notes that the transparent storage capacitor also has a “holding capacitance” that can stabilize the writing voltage to the storage capacitor if the “holding capacitance” is larger than the storage capacitance for the operation of the OLED. Other references that describe bottom-emitting OLED displays where the driving circuitry for each pixel contains a storage capacitor, which has the structure of transparent anode/insulating layer/transparent conductive layer, located in the emission path include: U.S. Pat. No. 10,446,633B2, CN109244107B, U.S. Pat. No. 9,601,553B2, US20150214249A1, U.S. Pat. No. 9,385,171B2, CN109166895B; CN109119440B, and U.S. Pat. No. 8,102,476B2. However, in all the above references, the transparent capacitor is part of the driving circuit and being the same size as the pixel, may not increase the overall capacitance enough to prevent ESD damage.

U.S. Pat. Nos. 8,941,143 and 9,487,878 describe segmented OLEDs with electrically conductive tracks that extend though the device and which are in contact with a hole-injection track. U.S. Pat. No. 9,487,878 also describes the use of conductive tracks that vary in thickness (height) or width from the outside to the inside segments to address the problem of IR drop. A similar concept of conductive layers with thickness variations to address IR drop is disclosed in U.S. Pat. No. 9,159,945.

U.S. Pat. No. 10,068,958 describes a segmented OLED where electrically conductive tracks are located between the segments.

U.S. Pat. No. 9,627,643 describes an OLED with electrically conductive tracks where the OLED electrodes and the conductive tracks are all transparent.

A need exists for protecting bottom-emitting segmented OLED devices with at least one small OLED segment against ESD damage where the protection is provided even when the device is not operating.

### SUMMARY

A segmented bottom-emitting OLED device compromising an array of multiple OLED segments arranged on a common transparent substrate, where the array forms an emitting area where each OLED segment is separated by a non-emitting gap; wherein each OLED segment is defined by a transparent bottom electrode segment, organic layers for light emission, and a top electrode; wherein between the bottom electrode segment and the substrate in at least one OLED segment, there is a transparent insulating layer that is closer to the bottom electrode segment and a transparent conductive layer that is closer to the substrate, such that the area of overlap between the bottom electrode and the conductive layer forms an associated passive capacitor structure, where the bottom electrode of the OLED segment is the upper electrode of the passive capacitor structure, the insulating layer is the dielectric of the passive capacitor structure, and the conductive layer is the lower electrode of the passive capacitor structure.

The above OLED device where the conductive layer is patterned. The conductive layer can be patterned into two or more sections that are electrically isolated from one another.

Any of the above OLED devices where in at least one OLED segment, the area of the overlap between the conductive layer section(s) and the bottom electrode segment increases the total capacitance of the OLED segment by at least 0.2 nanoFarads (nF). Any of the above OLED devices where in at least one OLED segment, the area of the overlap between the conductive layer section(s) and the bottom electrode segment is 30% or more of the area of the bottom electrode segment.

Any of the above OLED devices where, in addition to those OLED segments with an associated passive capacitor structure, the bottom electrode segment of at least one different OLED segment in the array does not have any overlap with a conductive layer section so that no passive capacitor structure is associated with the at least one different OLED segment. The size of the at least one different OLED segment without the passive capacitor structure can be 1.0 cm² or more.

Any of the above OLED devices wherein the bottom electrode of each OLED segment in the array is electrically connected to a dedicated power feed which controls the light emission, where the power feeds are arranged laterally between the bottom electrode segments and are electrically isolated from other power feeds and any independent electrode segments.

Any of the above OLED devices wherein the bottom electrode segment of each OLED segment in the array is electrically connected to a single power feed which controls the light emission, wherein the power feeds are arranged laterally between the conductive layer sections and are electrically isolated from other power feeds and the conductive layer sections as well as being electrically isolated by the insulating layer from the bottom electrode segments of any independent OLED segments. The dedicated power feeds can be connected to the corresponding bottom electrode segments through vias in the insulating layer. Any of these OLED devices wherein at least one of the power feeds is arranged to pass beneath at least one bottom electrode segment in the emission area of an independent OLED segment.

Any of the above OLED devices wherein there are multiple power feeds beneath the bottom electrode segment of at least one independent OLED segment such that the overlap between all of the power feeds and the bottom electrode of an independent OLED segment forms an associated passive capacitor structure, where the bottom electrode segment is the upper electrode of the passive capacitor structure, the insulating layer is the dielectric of the passive capacitor structure, and the multiple power feeds together are the lower electrode of the passive capacitor structure. In at least one independent OLED segment, the area of the overlap between the multiple power feeds and the bottom electrode segment in the associated passive capacitor structure increases the total capacitance of an independent OLED segment by at least 0.2 nF or the total overlap between the sum area of power feeds and the overlying bottom electrode in the associated passive capacitor structure of the independent OLED segment is 30% or more of the area of the bottom electrode segment.

The bottom-emitting segmented OLED devices as described provide an on-substrate transparent passive capacitor structure located within the emission path of the OLED segment with sufficient capacitance to provide, in combination with the inherent capacitance of the associated OLED segment, protection against electrostatic protection. Not only does this provide ESD protection in the unpowered state, locating the passive capacitor structure directly under the segmented electrode also maximizes the total possible emitting area of the device.

### BRIEF DESCRIPTION OF THE DRAWINGS

FIG. 1A is a top-view of an inventive segmented OLED device 100 with five segments with a conductive layer that is the lower electrode for a passive capacitance which is located under all OLED segments. The power feeds are located laterally to the electrode segments. FIG. 1B is a cross-section view of 100. FIG. 1C shows a circuit diagram for 100.

FIG. 2A is a top-view of an inventive segmented OLED device 200 with five segments with a conductive layer that is the lower electrode for a passive capacitance which is located under some of OLED segments. The power feeds are located laterally to the electrode segments. FIG. 2B is a cross-section view of 200.

FIG. 3A is a top-view of an inventive segmented OLED device 300 with five segments with a conductive layer that is the lower electrode for a passive capacitance and partially overlaps with some of OLED segments. The power feeds are located laterally to the electrode segments. FIG. 3B is a cross-section view of 300.

FIG. 4A is a top-view of an inventive segmented OLED device 400 with five segments with a conductive layer that is the lower electrode for a passive capacitance and is located under some of OLED segments along with the power feeds. FIG. 4B is a cross-section view of 400.

FIG. 5A is a top-view of an inventive segmented OLED device 500 with seven segments with a conductive layer that is the lower electrode for a passive capacitance and is located under some of OLED segments along with the power feeds, some of which pass below a segmented electrode without electrical contact. FIG. 5B is a cross-section view of 500.

FIG. 6A is a partial top-view along one side of a segmented OLED device 600 where multiple power feeds pass below a segmented electrode without electrical contact. FIG. 6B is a partial cross-section of 600.

FIG. 7 shows a cross-sectional schematic for a two stack OLED formulation 1000.

FIG. 8 shows a test circuit for determining ESD sensitivity.

The figures are not to scale.

### DETAILED DESCRIPTION

For the purposes of this disclosure, the terms “over” or “above” mean that the structure involved is located above another structure, that is, on the side opposite from the substrate. “Uppermost” or “upper” refers to a side or surface furthest from the substrate while “lower”, “bottommost”, “below”, “underneath” or “bottom” refers to the side or surface closest to the substrate. Unless otherwise noted, “over” should be interpreted as either that the two structures may be in direct contact or there may be intermediate layers between them. By “layer”, it should be understood that a layer has two sides or surfaces (an uppermost and bottommost) and that multiple layers could be present and is not limited to a single layer. “LEL” always refers to a single light-emitting layer. “Unit” generally indicates a minimum of one layer that can be considered to act as one single source of light; a unit may be equivalent to a single LEL, may contain one LEL associated with other non-emitting layers, or may have multiple LELs with or without additional layers. A light-emitting unit is a grouping of one or more LELs that are separated from another light-emitting unit by a charge-generating layer (CGL). Thus, if an OLED device does not have a CGL, there is only one light-emitting unit, even though it may have multiple LELs. Such a device is often referred to as a “one-stack” device. If an OLED device has two light-emitting units, separated by a CGL, then it can be referred to as a “two-stack” device. A stacked OLED may have multiple units or combinations of units and LELs, that together make up the total emission.

R or “red” indicates a layer or unit that primarily emits red light (>600 nm, desirably in the range of 620-660 nm), G indicates that a layer or unit primarily emits green light (500-600 nm, desirably in the range of 540-565 nm) and B indicates a layer or unit that primarily emits blue light (<500 nm, desirably in the range of 440-485 nm). It is important to note that R, G and B layers can produce some degree of light outside the indicated range, but the amount is always less than the primary color. Y (yellow) indicates that a layer or unit emits significant amounts of both R and G light with a much lesser amount of B light. Unless otherwise noted, wavelengths are expressed in vacuum values and not in-situ values.

The OLED light-emitting element of the invention can be a single LEL, a single-stack OLED, a two-stack OLED, or even three or more OLED stacks, which can emit a single color or multiple colors. If a single-color light output is desired or the color temperature of the light output needs to be adjusted or modified, color filters may be used to eliminate any unwanted wavelengths.

An OLED light-emitting LEL or unit can produce a single “color” of light (i.e., R, G, B, combination colors of 2 primary colors, such as Y or cyan, or W). The individual OLED light-emitting units may have a single light-emissive layer or may have more than one light-emitting layer (either directly adjacent to each other or separated from each other by an interlayer). The individual light-emitting units may also contain various kinds of non-emitting layers such as hole transporting layers, electron-transporting layers, blocking layers and others known in the art to provide desirable effects such as promoting emission and managing charge transfer across the light-emitting unit. The single color of light may be generated within the OLED unit by a single layer with one or more emitters of the same color or multiple layers, each with the same or different emitters whose primary emission fall within the same color. The single color provided by the OLED unit can be a combination of two primary colors; in particular, a yellow light-emitting OLED unit that produces a combination of R and G light. In this case, yellow counts as a single color.

A stacked OLED device can produce a single color of light or more than one color of light (multimodal). For example, a multimodal OLED produces a white light with roughly equal amounts of R, G and B light. Typically, this would correspond to CIEₓ, CIE_{y} values of approximately 0.33, 0.33. White light, even if does not contain equal amount of R, G, B light, can generally be produced in OLEDs by having three separate R, G and B light-emitting layers, two separate light emitting layers such as blue and yellow, or even a single white light-emitting layer. A red light-emitting OLED would have CIEₓ, CIE_{y} values of approximately 0.6-0.7, 0.2-0.35. The OLEDs of the invention may utilize a microcavity effect to increase the emission of a desired color of light.

For specific applications such as automobile taillights which are used to signal braking, stopping, turning and other functions, the light-output of the OLED used should be chosen to meet all government regulations and SAE or industry standards that apply to that use, particularly in terms of color and luminance. In addition, the size and dimensions of the segmented OLED device should be chosen to conform to all appropriate government regulations and industry standards that apply to the particular use. For such taillight applications, the preferred emission color is red.

The segmented OLED device, which is comprised of multiple individual OLED segments on a common substrate, may have any shape as desired. It may be entirely flat or planar, may have multiple planar surfaces angled to each other, may be entirely curved, or may have a mixture of flat, angled or curved surfaces. The segmented OLED devices will often be mounted in a housing or part of a module, along with any necessary external power connections and control elements that supply a signal or power to the individual segments. The housing or module will typically have transparent sections that allow the light for the OLED device to pass out and yet provide protection from the outside environment. The housing or module might also have internal reflectors or light guides to help direct light emission as desired. The entire housing or module containing the segmented OLED device can be hermetically sealed.

In a segmented OLED device, each individual OLED segment should have uniform light emission across the active area of the segment, is not subdivided and is powered by a single source (power feed) and signal. A segmented OLED device with individually controlled segments arranged in an array can be used for lighting purposes where all segments are activated at the same time to provide uniform light emission (except for the gaps between the segments). The light emission across all segments can be constant, dimming as one, brightening as one or flashing on/off. Alternatively, the segmented OLED device can have each segment activated individually and independently in some sort of a pattern. The pattern may involve some segments which are fully on, some at intermediate luminance levels and some that are off. The pattern may be unchanging over some period of time or may be moving, where the individual segments are activated on/off in some type of time-based or location-based sequence. Since segmented OLED devices are not high-resolution displays and are typically meant to be viewed from a substantial distance, the individual OLED segments are substantially larger than the individual pixels in a high-resolution display (which typically have an emission area much less than 0.1 mm²). Desirably, for smaller segmented OLED devices with a total emission area of 500 cm² or less, the individual OLED segments should have an emission area of at least 0.025 cm² and desirably at least 0.05 cm². For larger sized segmented devices with a total emission area of greater than 500 cm², the individual OLED segments should have an emission area of at least 0.05 cm² and more desirably at least 0.5 cm².

The individual OLED segments can be of any shape or area as desired. Generally, in order to minimize the non-emitting space between the individual segments, the segments will form a packed array. Desirably, the array is a regular array so that the spacing between the segments is uniform and provides a sleek appearance. The array can take any overall form in terms of shape and need not be square or rectangular, but also can be circular, oval, triangular, or polygonal. In some designs, some areas of the array are regular with uniform spacing between them and other parts of the array are irregular. For example, in a square array, the outside of the array can have smaller square segments set in a uniform pattern while the interior area has a single larger star shaped segment in the exact center surrounded a large non-emitting area. Likewise, the shape of individual OLED segments within the array are not limited, but can be square, rectangular, circular, oval, triangular, or polygonal or even irregular as desired.

Moreover, the OLED segments within the array need not be all the same shape, but may have a mixture of shapes such as, for example, interlocked triangles and hexagons. Preferred are packed arrays with only triangles, only parallelograms or a mixture of triangles and hexagons or triangles and trapezoids. The individual segments may not have all the same area and the array may be composed of a mixture of large and small segments. The individual segments in the array need not emit the same color (although each individual segment will emit a single color) and the segments that emit different colors can be located in a specific pattern within the array. Desirably, the array of segments is unsymmetrical; that is contains segments of different sizes and more desirably, the array contains segments of different sizes and shapes.

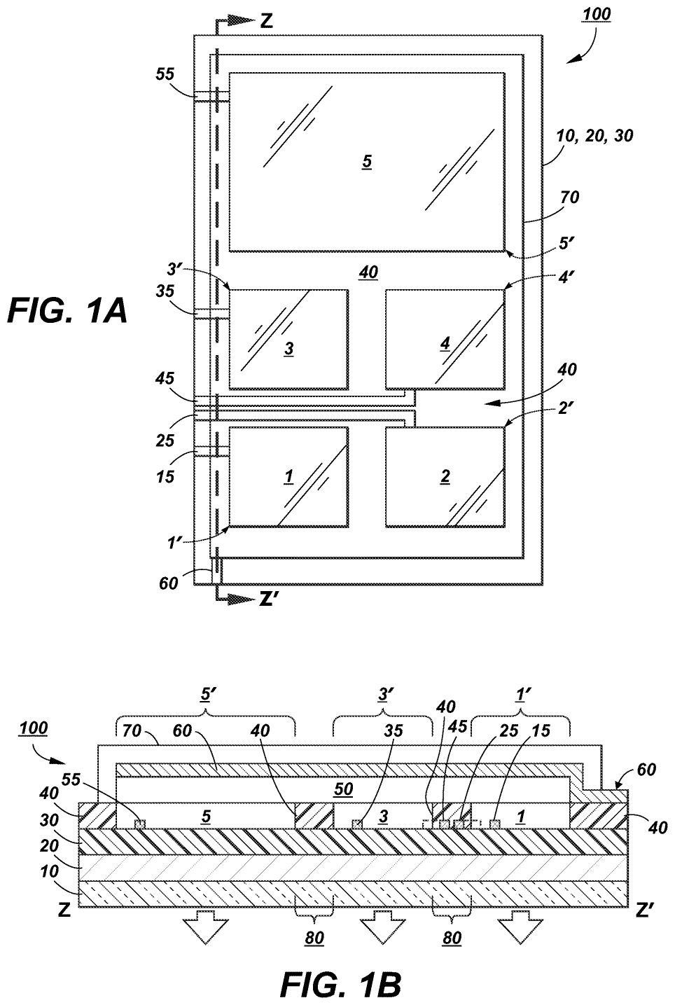

FIG. 1A shows an overhead view of a segmented OLED device 100. There are five different OLED segments 1′, 2′, 3′, 4′ and 5′ as defined by the transparent electrode segments 1, 2, 3, 4 and 5. In this example, OLED segment 5′ has an area of greater than 1 cm² and the area of segments 1′-4′ are less than 1 cm². The OLED segments 1′-5′ are arranged as an asymmetric array on top of a transparent substrate 10 where the outer edges of the array represent the emission area of 100. On top of the transparent substrate 10 are a uniform transparent conductive layer 20 and a uniform transparent insulating layer 30. Both 20 and 30 are not patterned. On top the insulating layer 30, there is a power feed 15 that is electrically connected to electrode segment 1, a power feed 25 connected to electrode segment 2, a power feed 35 connected to electrode segment 3, a power feed 45 connected to electrode segment 4, and a power feed 55 connected to electrode segment 5, all of which occupy the same lateral plane. There is an electrically insulating pixel definition layer (PDL) 40 between the electrode segments as well as between any adjacent power feeds or between any adjacent electrode segment and power feed. Because the power feeds may not be as thick as the electrode segments, the PDL 40 may also be deposited over the top surface of the power feeds in order to planarize the top surface of the PDL/electrode segment layer. There should be no electrical contact between any of these electrode segments and power feeds except for the point of contact between the electrode segment and its designated power feed. Over the surface of the PDL 40/electrode segments 1-5 are organic layers for light emission 50 (not shown in this view) and a common top electrode 60. There is an encapsulation layer 70 over the electrode 60. One end of each the power feeds as well as the top electrode 60 extends outside the encapsulation 70 to form contact pads for individual connection to the control circuitry for 100. There is a non-emitting gap or space 80 between the OLED segments (and within the emission area of the array) which typically corresponds to the location of PDL 40.

FIG. 1B shows a cross-section of segmented OLED device 100 along the line Z-Z′ of FIG. 1A. Visible in this view are organic layers 50 for light emission, a continuous top electrode 60 that is common across all OLED electrode segments 1-5 and which extends past the encapsulation 70 on one side to form an external contact pad for connection to the control circuitry. The arrows indicate the direction of light emission from the individual OLED segments 1′-5′. In this embodiment, the power feeds 15, 25, 35, 45 and 55 are shown as being less thick than the electrode segments and their upper surfaces are covered with PDL 40 to create a flat upper surface across the electrode segments and the PDL located between the electrode segments. Between electrode segments (e.g., between 3 and 5), PDL 40 provides non-emitting gaps 80.

The OLED structures (bottom electrode segments (1-5)/organic layers (50)/common top electrode (60)) in OLED segments 1′-5′ each are capacitor structures having an associated inherent capacitance. The inherent capacitance (C_{OLED}) of the OLED structure in each segment will depend, among other factors, on the size of the bottom electrode segment since the top electrode 60 is common to all. C_{OLED} would be associated with only the light-emitting OLED part (top electrode to bottom electrode) of the OLED segment.

In 100, on the substrate side of the electrode segments 1-5, there is an insulating layer 30 and a conductive layer 20, which are both continuous and uniform above the upper surface of the transparent substrate 10. Within a single OLED segment, this could form a multiplanar capacitor structure where there is a top OLED capacitor structure consisting of the top electrode/organic layers (dielectric)/bottom electrode segment and a bottom passive capacitor structure consisting of the bottom electrode segment/insulating layer (dielectric)/conductive layer. It is important to note that even though the conductive layer 20 is not directly electrically connected to any part of the overlying OLED structures, it can still serve as a lower electrode for a passive capacitor structure because the conductive layer is common to the other OLED segments. In 100, the capacitance (C_{PASSIVE}) of the passive capacitor structure in each OLED segment will depend, among other factors, on the size of the bottom electrode segment of the OLED since the conductive layer 20 is common to all. In this embodiment, the vertical overlap between the bottom electrode segments and the conductive layer is 100% of the electrode segment.

In 100, there are five passive capacitor structures that are formed; one for each OLED segment 1′-5′ where the conductive layer overlaps with the individual electrode segments 1-5. These five passive capacitor structures, which are connected in parallel relative to each other, share the same conductive layer 20 (lower electrode) and insulating layer 30 (dielectric), and differ only because of the different OLED electrode segments. Even though the common conductive layer 20 is shared between different OLED segments, the passive capacitor structure for any one OLED segment is according to the overlap between the bottom electrode of the OLED and only that part of the conductive layer directly below that bottom electrode. In an OLED segment of the invention, the OLED (as a capacitor structure) and the passive capacitor structure are directly associated with each other because both structures share the bottom electrode of the OLED. The conductive layer 20 (which is the lower electrode of the passive capacitor structure) is not directly connected to any circuit.

FIG. 1C shows a circuit diagram for 100 where the OLED segments are connected to control circuit 95 via power feeds 15, 25, 35, 45 and 55. During operation, the control circuit can activate the OLED segments 1′-5′ independently as desired. In an unpowered state, each of the five OLED segments 1′-5′ will be a multiplanar capacitor where one capacitor part is an OLED structure with individual inherent capacitances C_{O1′}-C_{O5′} and the other capacitor part is an associated passive capacitor structure with individual capacitances C_{P1′}-C_{P5′}. The bottom electrode segment (i.e., 1 in OLED segment 1′) serves both as the lower electrode of the OLED structure and as the upper electrode for the passive capacitor structure. The lower electrode of the passive capacitor structure is conductive layer 20 which is common with the passive capacitor structures in the other OLED segments. Within an individual OLED segment, the OLED structure and the associated passive capacitor structure are connected in series and the capacitance of that OLED segment as a multiplanar capacitor will be equal to C_{OLED}*C_{PASSIVE}/(C_{OLED}+C_{PASSIVE}).

However, because the lower electrode (conductive layer 20) of the passive capacitor structure in one OLED segment is common with the passive capacitor structures in other OLED segments, C_{PASSIVE} in one OLED segment is connected in parallel with all of the other OLED segments that share the same conductive layer. Thus, C_{PASSIVE} of any one OLED segment is the capacitance of the passive capacitor structure of the individual OLED segment together with the sum total of all of the capacitances of the other OLED segments.

Electrostatic charge on a device such as OLED device 100 can arise, and subsequently be discharged, via several pathways. The charge can come from above or below the device. A charge from above would encounter top electrode 60. A charge from below would pass through substrate 10 and encounter conductive layer 20. In either case, top electrode 60 or conductive layer 20 would disperse the electrostatic charge across a substantial area, and any discharge would occur across numerous segments of OLED device 100 (i.e., across a parallel array of multiplanar capacitors as above), and would be less likely to cause damage to the device.

A more problematic pathway for electrostatic charge and discharge would be if an individual bottom electrode became charged. This could occur elsewhere in the device and be carried by a power feed (e.g., 15) to the corresponding bottom electrode segment (e.g., 1). The danger of this pathway is that the electrostatic charge on a single bottom electrode segment is likely, without any mitigating factors, to be discharged through a single OLED segment, or at most a few neighboring OLED segments, potentially damaging those OLED segments. Thus, for the purposes of this invention, it will be assumed that any electrostatic charge occurs on a bottom electrode segment, and the capacitance of the corresponding OLED segment will be the capacitance that is available at the bottom electrode: across the capacitance of the OLED structure of 1′ (C_{OLED}), and across the capacitance provided by the passive capacitor structure comprising bottom electrode 1, conductive layer 20, and the intervening dielectric layer (C_{PASSIVE}). However, conductive layer 20 is common with the passive capacitor structures in other OLED segments, thus connecting C_{P1′} in series with a parallel array of the other capacitances. In FIG. 1C, this is shown by OLED segments 2′ through 5′ connected in a parallel array which in turn is connected in series to C_{P1′}.

In general, for an array of n OLED segments (assuming equal size), the overall total capacitance (C_{T}) of any individual OLED segment at the bottom electrode is the sum of the capacitance of the associated OLED segment (C_{OLED}) and the capacitance of the passive capacitor structure (C_{PASSIVE}) in series with the capacitances of the other n−1 OLED segments arranged in parallel, where each of the n−1 OLED segments is a multiplanar capacitor with C_{OLED} and C_{PASSIVE} in series, as described above. The total effective capacitance (C_{T}) is according to the following formula:

$${C}_{T} = {C}_{OLED} + {C}_{PASSIVE} \times [ ( n - 1 ) \cdot {C}_{OLED} / ( {C}_{PASSIVE} + n \cdot ( {C}_{OLED} ) ]$$

Note that as the number of segments becomes large, the added capacitance due to the passive capacitor structure can be approximated by the value added for a single OLED segment:

C_{T}˜C_{OLED}+C_{PASSIVE}(for large n)

For arrays with different OLED sizes, the capacitances would be individually summed, but would still be approximated by the value added for a single average OLED segment if n is large enough.

Because the sizes of the OLED segments are primarily selected to meet the light emission aims and requirements of the device, they may have insufficient inherent capacitance to protect against ESD damage; this capacitance can be increased within the array by the addition of the passive capacitor structures across OLED segments to form an array of OLED segments where at least some OLED segments are each associated with a passive capacitor structure. The addition of this passive capacitor structure increases the total capacitance which will decrease its susceptibility to ESD damage. Because the total capacitance of the OLED segment has been increased by the addition of the passive capacitor structure(s), any electrostatic charge can be better dissipated and thus, damage to the organic layers in the overlying OLED structure can be mitigated.

In particular, the passive capacitor structure(s) should provide an increase in total capacitance of the OLED segment relative to the same OLED segment without the passive capacitor structure. This additional capacitance should be enough to provide the desired level of protection against ESD damage. The sensitivity of an OLED to ESD damage is according to V_{LIM}, which is a voltage limit above which damage to the OLED is expected. V_{LIM} is an inherent characteristic of the OLED formulation, can vary greatly between different OLED formulations and is independent of the size of the OLED. V_{LIM} can be determined experimentally. Increasing the overall capacitance of the OLED segment will decrease the voltage experienced by the OLED from electrostatic discharge and so, maintain the voltage experienced by the OLED below V_{LIM}. Thus, it is desirable that the sum capacitance provided by the passive capacitor structure(s) when added to the inherent capacitance of the OLED part of the segment is sufficient to raise the total capacitance of the OLED segment such that the voltage experienced during an ESD event is maintained below V_{LIM}.

The area (size) of the individual OLED segment is important in determining the susceptibility to damage from ESD. Larger segments with an emission area of greater than 1.0 cm² or more generally have an inherent capacitance sufficient to dissipate ESD without damage. OLED segments of 1.0 cm² or less, and especially less than 0.5 cm² can be prone to ESD damage because their inherent capacitance is not as high. Thus, in a segmented OLED device with segments that have different sizes, it may not be necessary to provide the larger segments with additional ESD protection by adding an associated passive capacitor structure. For example, ESD protection may not be needed for OLED segment 5′ in 100 because of its size (>1 cm²), while segments 1′-4′ still require protection. Moreover, the presence of a passive capacitor structure with a monolithic common conductor layer as the lower electrode can depress response time (frequency) of the OLED. By patterning the conductive layer into smaller sections, this decrease can be minimized.

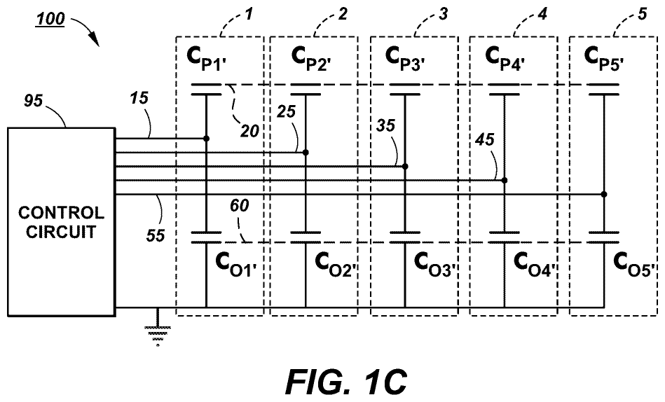

This protection arrangement is shown in FIGS. 2A and 2B, which are respectively top and cross-section views, for OLED device 200 which is similar to 100, but the passive capacitor structure is not present under all electrode segments. In particular, conductive layer 20 is not continuous under all OLED segments, but is patterned to be under OLED segments 1′-4′ but not under 5′. Instead, another insulating layer 31 is added under electrode segment 5. Insulating layer 31 is also transparent and may be the same or different from insulating layer 30. In this way, the total capacitance for the smaller OLED segments 1′-4′ is increased in a manner similar as described for 100, while the capacitance of the larger OLED segment 5′ is relatively unaffected. In this embodiment, the vertical overlap between the bottom electrode segments 1-4 in OLED segments 1′-4′ and the conductive layer 20 is 100%.

In 100 and 200, there is also a 3^{rd} capacitor structure formed between a power lead which is laterally separated from a bottom electrode segment to which the power feed is not connected. For example, power lead 25 is laterally separated from bottom electrode segment 1 by the PDL 40. This forms a passive capacitor structure since power feed 25 is not connected to electrode segment 1 (power feed 25 is connected to electrode segment 2). Although the power feeds carry current during the operation of the OLED device, they are not powered when the device is not in operation (which is the time at which ESD protection is needed) and so can help dissipate ESD passively. However, since both the power feeds and bottom electrodes are thin, the area of overlap between the side of the power feed and the side of the bottom electrode segment is relatively small, the capacitance will be small and so, its contribution to the total capacitance in this case will be negligible.

In both 100 and 200, the relative area of overlap (when present) between the bottom electrode segments and the underlying conductive layer 20 that forms the passive capacitor structure is 100%. That is, the conductive layer 20 that provides the passive capacitor structure is equal to or larger in area than the corresponding electrode segment. Since it is only necessary to increase the total capacitance to a level sufficient to provide ESD protection, the relative area of the conductive layer 20 that forms the passive capacitor structure may be less than 100% of the corresponding bottom electrode segment. Even though the capacitance would be smaller than when the relative overlap area is 100%, the overall capacitance may be sufficient to prevent ESD damage when added to the inherent capacitance of the OLED.

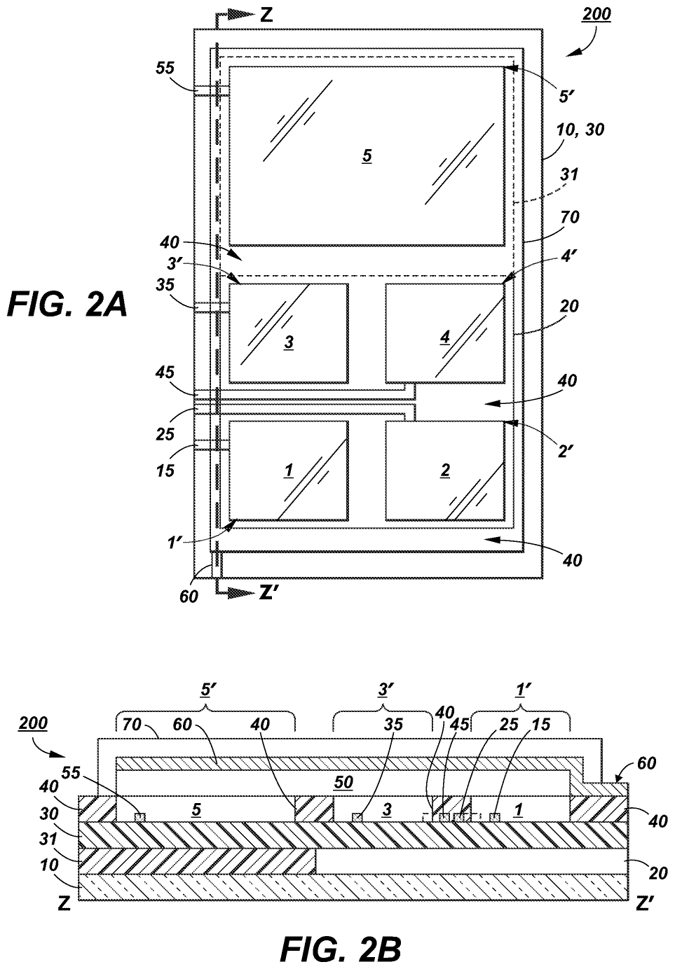

This is illustrated in FIGS. 3A and 3B, which are respectively top and cross-section views, for a segmented OLED device 300 which is similar to 200 but where the overlap area between the electrode segment and the conductive layer that forms the second passive capacitor is less than 100%. In particular, the conductive layer 20 has been patterned so that the area of overlap (90) with each of the bottom electrode segments 1-4 is 50%; that is, the conductive layer 20 that forms the lower electrode of the passive capacitor structure only overlaps about 50% of each of the overlying electrode segments 1-4 that form the upper electrode of the passive capacitor structure.

The amount of overlap between the conductive layer and the bottom electrode segment is related to the capacitance provided by the passive capacitor. Ideally, the area of overlap between the conductive layer and the electrode segment that forms the passive capacitor structure should be at least 30% or more in order to provide a significant amount of capacitance. That is, the area of the conductive layer or total area of all conductive layer sections present (which forms the lower electrode of the second capacitor structure) that overlaps with the electrode segment (which is the upper electrode of the second capacitor structure) is at least 30% of the area of the electrode segment. More desirably, the area of overlap is at least 50% or more and most desirably, at least 70% or more.

In some examples of segmented OLED devices, it may not be desirable to locate the power feeds between and laterally separated from the electrode segments. Such an arrangement can be prone to shorting due to manufacturing defects. Moreover, depending on the layout, overall size and number of OLED segments, it may not be possible to fit all of the necessary power leads (at least one per OLED segment) within the available distance (non-emitting gap) between the OLED segments. Some power feeds may have increased width (to minimize IR drop over their length) that cannot be accommodated within the available gap distance. In these cases, the powers feeds can be located below the plane of the electrode segments and above the transparent substrate.

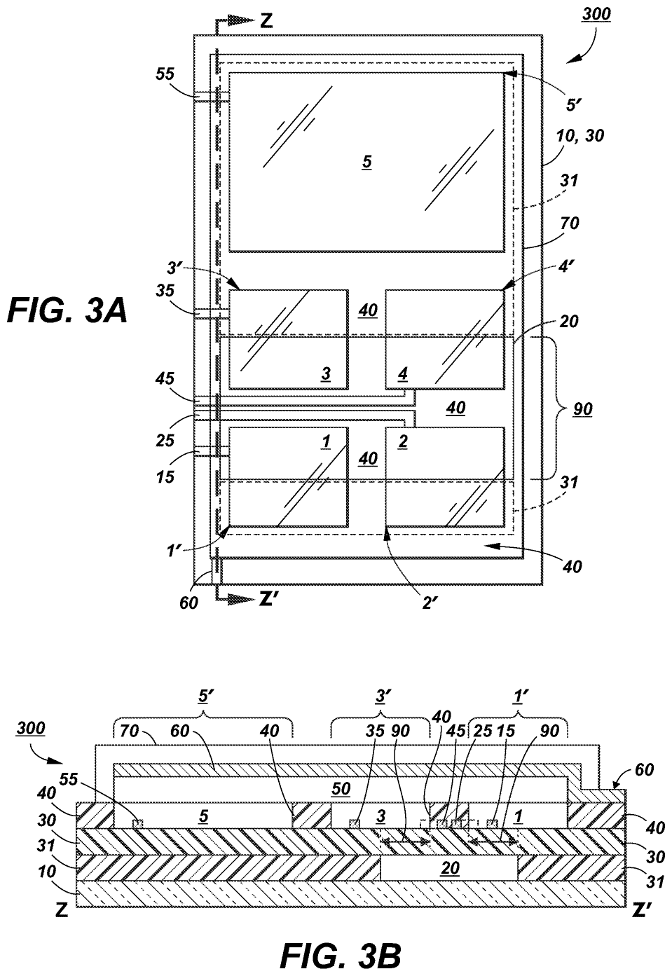

FIG. 4A shows a top view of a segmented OLED device 400 in which the power feeds are located between the plane of the electrode segments and the transparent substrate and not in the same plane as the electrode segments. In particular, the power feeds 15, 25, 35, 45, 55 are located over the transparent substrate 10 in the same lateral plane as the conductive layer. In this example, the conductive layer has been patterned into two separate conductive layers 22 and 24. Power feed 15 is separated from electrical contact with conductive layer 22 by insulating layer 31 in the form of a slot in 22. Power feeds 25 and 45 are located in the space between 22 and 24 and separated from electrical contact by insulating layer 31. Power feeds 35 and 55 are separated from electrical contact with conductive layer 24 by insulating layer 31 (which can be the same or different from the insulating layer 30) in the form of a slot in 24. In no case are the power feeds in electrical contact with any part of the conductive layer. The power feeds make contact with the appropriate electrode segment through vias through insulating layer 30 or 31, or both.

FIG. 4B shows a cross-section of 400 along the line Z-Z′. In 400, the power feeds 25 and 45 are located directly below the non-emitting spaces between the electrode segments and so, are not in the emission path. The power feeds 15, 35, 55 are connected to the electrode segments 1, 3 and 5 though vias 32 in the insulating layer 30 (the vias for power feeds 25, 45 are not shown).

However, this may not always be possible since the non-emitting space 80 may have insufficient space for the number of power feeds required. In this case, it is necessary to locate at least some of the power feeds below the electrode segments in the same plane as the conductive layer. The insulating layer 30, located between the upper surface of the conductive layer and any power feed and the bottom surface of the electrode segments, prevents any electrical contact between the power feed and any electrode segment it does not control.

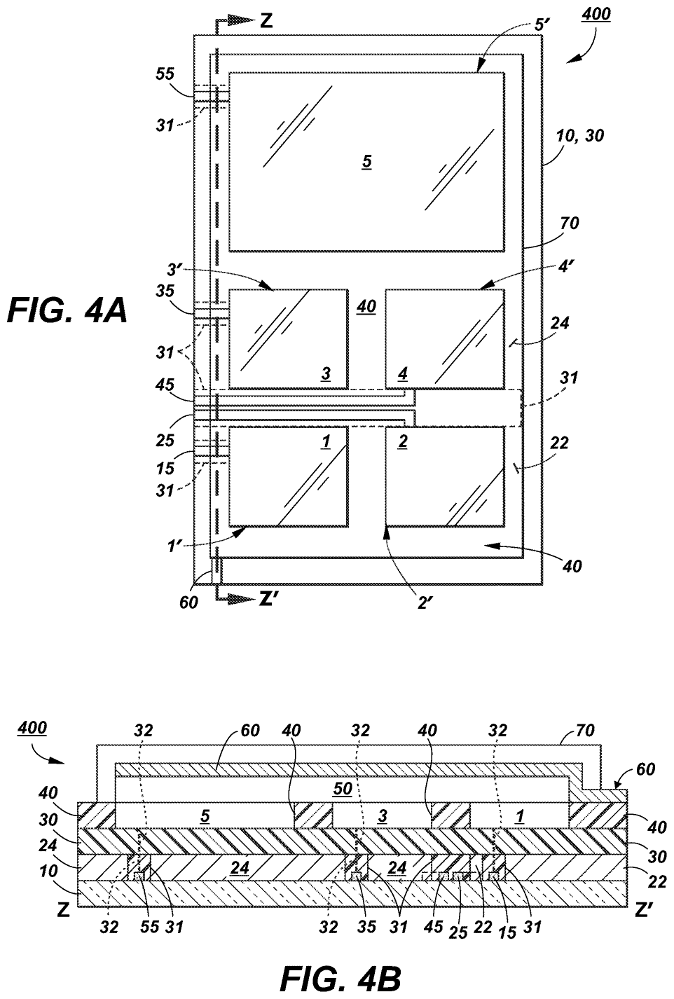

Since it is not always possible to run all of the power feeds below the non-emitting gaps between the electrode segments, it may be necessary to run at least some of the power feeds beneath (and electrically isolated from) one or more bottom electrode of the OLED segments, even though they are located in the emission pathway. This situation is shown in FIG. 5A, a top view of a segmented OLED device 500 which is a heterogeneous array of seven individual OLED segments.

In 500, there are two columns of three OLED segments each; 1′-3′ (as defined by the corresponding bottom electrode segments 1-3) in one column and 5′-7′ (as defined by the corresponding bottom electrode segments 5-7). The two columns are separated by a single larger segment 4′ (as defined by the corresponding bottom electrode segment 4). Over a transparent substrate 10 are power feeds (15, 25, 35, 45, 55, 65, 75) for each corresponding electrode segment (1-7), all of which are located between three sections (22, 24, 26) of a conductive layer. The power feeds are electrically insulated from each other as well as the conductive layer sections 22, 24, 26 by an insulating layer 31. Not shown in FIG. 5A (but visible in FIG. 5B) is an insulating layer 30 over the power feeds/conductive layer sections 22, 24, 26/insulating layer 31, followed by the electrode segments 1-7 which are laterally separated by a PDL 40, along with organic layers for light emission 50, a common top electrode 60 and encapsulation 70.

In 500, there are different passive capacitor structures formed by the overlap between electrode segments 1 and 5 with conductive layer section 22, by the overlap of electrode segments 2 and 6 with conductive layer section 24 and by the overlap of electrode segments 3 and 7 with conductive layer section 26. These passive capacitor structures are connected in parallel between the bottom electrode segment and the conductive layer sections. These passive capacitor structures increase the total capacitance of OLED segments 1′-3′ and 5′-7′ and so provide ESD protection. However, OLED segment 4′ has three different second capacitor structures where common electrode segment 4 overlaps with the individual conductive layer sections 22, 24, 26. In this case, the total capacitance of OLED segment 4′ is the inherent capacitance of the OLED+the sum of three capacitances of the passive capacitor structures formed between 4 and 22, 4 and 24, and 4 and 26.

In 500, all of the external contact pads for the power feeds are located on the same side of the substrate. This arrangement is very desirable for ease of manufacture as well as installation of the device. However, it is then necessary for some of the power feeds to lie directly under bottom electrode segment 4 in order to make contact with the bottom electrode segments 5-7 on the far side of the device. This can be seen in the cross-section of 500 along the line Z-Z′ and shown in FIG. 5B. In this embodiment, power feeds 55, 65 and 75 all lie below bottom electrode segment 4 and are electrically isolated from 4 by insulating layers 30 and 31. These power feeds all lie in the emission pathway from OLED segment 4′ and may be visible under some circumstances.

In OLED segment 4′ of 500, there are additional passive capacitor structures that are formed between the power feeds 55, 65 and 75 (which are conductive) and the overlying electrode segment 4 when the device is not in operation or where there is no power applied to those particular power feeds. This is because there is no electrical connection between these power feeds (which serve other electrode segments) and the overlying electrode segment 4, which is independent of the power feeds. During operation of the segmented OLED device, some of these power feeds may be powered and so, would not act as a passive capacitor structure at that time. However, since ESD protection is necessary when the device is not in operation, such an arrangement can still increase the total capacitance of the OLED segment.

In the specific example of 500, there are only three power feeds (which are relatively thin in width because there is only an array of seven OLED segments and so, IR drop is not a concern) located underneath the electrode segment 4 and so, the additional passive capacitance provided by the capacitor structures formed between the power feeds 55, 65 and 75 and bottom electrode segment 4 would be small because each of the corresponding passive capacitor structures are small. In this example, the overlap area between the power feeds 55, 65, 75 and electrode segment 4 is much less than 25% of the area of the electrode segment. As such, the additional capacitance due to these passive capacitor structures is negligible in this example.

However, a segmented OLED device can have a large number of individual segments; for example, 100-1000 segments. Since each segment has its own individual and unique power feed, there may be a large number of power feeds with their external contact pads located along one side of the substrate. Moreover, because of the size of such a large device, the power feeds may need to extend long distances and so, it might be necessary to increase their width (and overall conductivity) in order to prevent IR drop. In such instances, the OLED segments at or near the side of the array where the contact pads are located may have a large number of powers feeds for other segments located underneath the electrode segment. If the sum total of the overlap areas of the electrode segment with all of its underlying power feeds is at least 30%, more desirably at least 50%, and most desirably at least 70% or more, relative to the area of the independent electrode segment, this may be sufficient to provide sufficient ESD protection when the device is not in operation.

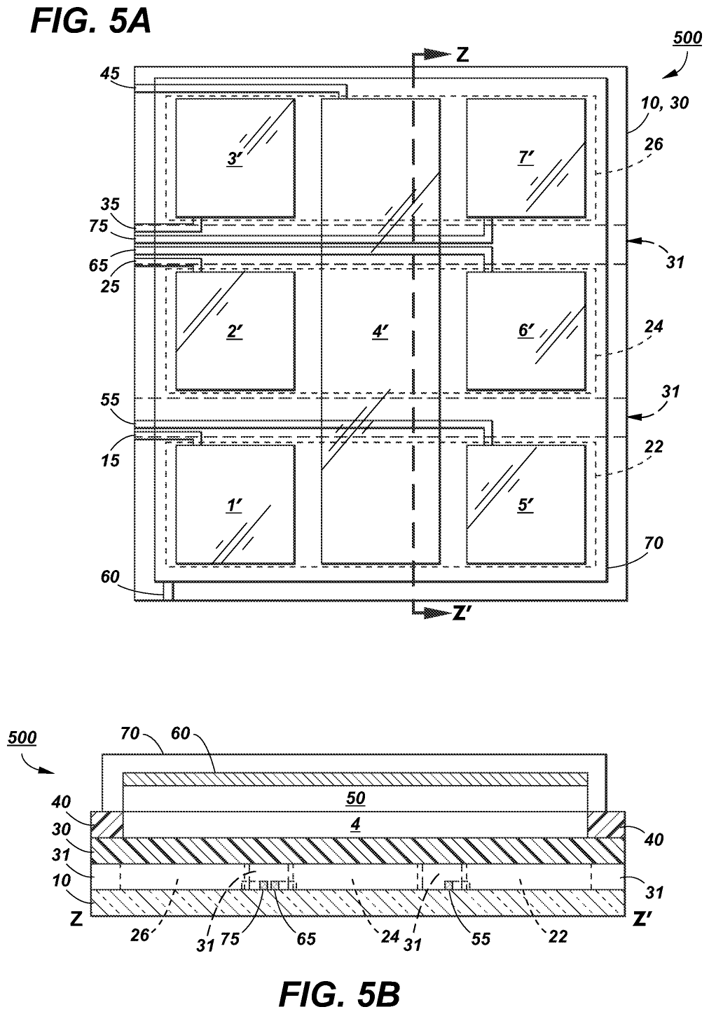

FIG. 6A shows a top view of a partial structure for a large segmented OLED device 600 where power feeds 601-615 all run beneath a single independent electrode segment 1 without being in electrical contact. This creates multiple areas of overlap 90 between each of the power feeds 601-615 and the overlying electrode segment 1, which is above all of these power feeds. Since power feeds 601-615 are not electrically connected to electrode segment 1, this forms multiple passive capacitor structures in the overlap areas 90. The power feeds 601-615 extend outside of the encapsulation 70 to form external contact pads along the same edge of the device 600. The power feeds in this example do not all have the same width; 601, 604, 607, 610 and 613 are all wider than the others. These wider power feeds are for connection to electrode segments that are relatively farther away from the end, and the increased width helps to minimize IR drop.

In this case, when the device is not in operation, the overlap between each power feed (acting as a lower electrode for a passive capacitor structure) and the overlying electrode segment (acting as a common upper electrode of the passive capacitor structure) form multiple passive capacitor structures, where each power feed is connected to another OLED segment. Since all of the OLED segments in the array are connected in parallel, the passive capacitance for the one OLED segment would be the capacitance according to total overlap of all of the underlying power feeds with the overlying (common) electrode segment plus the sum of the capacitances of the other independent OLED segments for which the power feed(s) also form a passive capacitor structure in a manner similar to that described for 100.

Since in this example, the sum total area of all of the passive capacitor structures formed by the overlap areas between the power feeds 601-615 and electrode segment 1 is greater than 50% of the area of the electrode segment, the total capacitance of this OLED segment (inherent OLED capacitance+sum of all passive capacitances resulting from the formation of a passive capacitor structure by the power feeds and electrode segment in addition to the capacitances of other independent OLED segments with the same power feed underneath), will provide increased protection from ESD damage whenever the device is not in operation or when those particular power feeds are not powered.

FIG. 6B shows the cross-section along line Z-Z′ of FIG. 6A of partial OLED device structure 600. In this example, there is no need for a separate conductive layer (i.e., 20 in the other figures) because the sum of the capacitances formed by the multiple passive capacitor structures (indicated by the arrows) formed by the power feeds and overlying independent electrode segment together with the inherent OLED capacitance is sufficient to provide ESD protection to this particular OLED segment. Effectively, there are enough power feeds present to act together, when the device is not operating, as the lower electrode of a passive capacitor structure sufficient to protect an overlying independent OLED segment so that a separate conductive layer section is not needed. The power feeds 601-615 can be located directly on the transparent substrate 10. The insulating layer 30, which acts as the shared dielectric layer of the passive capacitor structures, is located between and over the power feeds so there is no electrical contact between them or between them and the electrode segment 1. Organic layers 50, top electrode 60 and encapsulation 70 complete the OLED segment 1′ defined by electrode segment 1.

Because the capacitance is increased as more parallel passive capacitor structures (in this embodiment, formed between the power feeds and the bottom electrode segment of an independent OLED segment) that share a common lower electrode are added, it is desirable that the power feeds that act as the lower electrode of a passive capacitor structure also runs underneath the bottom electrode of more than one independent OLED segments; more desirably, under at least 5 independent segments and most desirably, 10 or more independent OLED segments. The use of the power feeds as a passive capacitor structure for some OLED segments in the array can also be used in combination with the use of a common conductive layer for other OLED segments.

The transparent substrate 10 can be glass (including flexible glass) or polymeric materials. Generally speaking, it will be flat with a uniform thickness. The top surface of the substrate is that facing the OLED. Since the substrate will be part of the overall encapsulation for the OLED, it should be sufficiently impervious to air and water so that the OLED will have desired lifetime. The substrate can be rigid or flexible. The substrate may have various types of subbing layers (i.e., planarization layers, light management layers, etc.) which may be patterned or unpatterned and can be located either on the top or bottom surfaces. Rigid or flexible glass is preferred.

The conductive layer 20 serves as the lower electrode of a passive capacitor structure which is separated from the bottom electrode segment of the OLED segment (which serves as the upper passive capacitor electrode) by an insulating layer. There is no direct electrical contact between the upper and lower capacitor electrodes. A passive capacitor structure is not electrically connected to any part of the control circuitry for those particular OLED segments for which it increases the overall capacitance. Its mere presence alone can provide a sump or reservoir to hold any ESD voltages. In particular, it is not involved in any way in the operation of the associated OLED segment including acting as a storage capacitor used to store power for an OLED segment for light emission. Desirably, it is electrically isolated (not directly electrically connected to any other circuitry at all) and merely serves to help dissipate any ESD charge through the involvement of the capacitance of the entire array. In some instances, the conductive layer may be connected to a ground, which will allow for faster dissipation, a voltage source which is separate and independent from the power source for the OLED segments, or even connected to the common top electrode of the OLED array.

The conductive layer 20 should be as transparent as possible since it will be in the emission pathway of the OLED segment. The conductive layer may be made of thin metal layers such as silver or copper, conductive metal oxides such as ITO, AZO, IZO, GZO, ZnO, TiN or SnO₂, organic materials such as PEDOT:PSS, CNTs (carbon nanotubes), graphene or conductive particles such as silver, nickel or copper suspended in a polymeric binder (conductive inks) or any combination of these materials. It may incorporate auxiliary structures such as metallic grid lines to improve electrical conductivity. It may be composed of multiple layers. Desirably, the conductive layer is a conductive metal oxide, particularly ITO or AZO.

Ideally, the conductive layer has a thickness of between 5 and 500 nm; desirably between 10 and 250 nm; and most desirably, between 20 and 150 nm.

The conductive layer 20 can be unpatterned where it is deposited as a single continuous and uniform layer across the entire surface of the substrate. However, in other embodiments, it may be patterned. For example, it could be patterned so that it is located only under the emission area of the array as a continuous and uniform layer. Alternatively, it could be patterned as a single continuous layer that is not uniform but contains features such as slots, cut-outs along the edges or internal openings.

The conductive layer 20 could also be patterned in sections so that there is one section that is a continuous layer under only some of the electrode segments but not all electrode segments. In such instances, the conductive layer is patterned into two or more sections that are electrically isolated from one another. For example, it could be patterned so that the individual sections are located only directly under each electrode segment. Alternatively, a single conductive layer section may be located under two or more electrode segments or a single electrode segment may be located over two or more different conductive layer segments. The different sections of the conductive layer may be laterally separated by a non-conductive or insulating material. There may be OLED segments in the array which do not have any conductive layer underneath the bottom electrode segment on the OLED structure. In such examples, there is no overlap.

Because in some instances not all OLED segments require additional ESD protection, it can also be desirable that the conductive layer overlaps with less than all OLED electrode segments. In particular, at least one OLED segment in the array may not have an associated passive capacitor structure. In an associated passive capacitor structure, the bottom electrode of the OLED structure also serves as the upper electrode of the passive capacitor structure in the same OLED segment. Because the additional capacitance necessary for ESD protection for any individual OLED segment depends on having additional parallel OLED segments with passive conductive structures, it can be desirable that the conductive layer overlaps with at least two OLED electrode segments. In particular, it would be desirable in some embodiments that the conductive layer overlaps with the electrode segments of at least two OLED segments, but less than all OLED segments so that at least one OLED segment does not have a passive capacitor structure. In some embodiments, it would be desirable that at least 20% of all the OLED segments have an associated passive capacitor structure, and more desirably, at least 50%.

The conductive layer 20 can be patterned using photolithographic techniques, deposited using masks, or deposited uniformly and then undesired portions removed (i.e., by laser ablation).

In embodiments where the power feeds for the individual OLED segments are located beneath an electrode segment to which they are not electrically connected (i.e., an independent OLED segment), the power feeds can form a passive capacitor structure with the overlying and unconnected (independent) electrode segment whenever the OLED device is not in operation (i.e., not connected to a power source) or whenever there is no current or voltage being applied through the power feed (i.e., the OLED segment is in the “OFF” state). In this way, the power feeds can serve an identical purpose and perform in the same manner as the conductive layer 20 in terms of ESD protection for these embodiments. However, it is necessary that the sum of the capacitances from the multiple passive capacitor structures formed between all of the power feeds and an electrode segment provide sufficient passive capacitance that, when added to the inherent OLED capacitance, that the total capacitance provides sufficient ESD protection. It should be noted that if the power feed is electrically connected to the overlying segment electrode, the resulting structure is not a capacitor.

There should be only one power feed per electrode segment and each power feed is electrically isolated from other power feeds as well as any independent electrode segments by a non-conductive or insulating material. By “independent”, it is meant any electrode segments (or the corresponding OLED segments) that are not connected to and are electrically isolated from that particular power feed. Thus, each OLED segment in an array has a single dedicated power feed to which it is electrically connected and all of the other OLED segments are independent of that power feed. In some instances, the power feed may be split into two or more sub-feeds which are connected in different locations to the same electrode segment. In some cases, two or more separate but commonly operated power feeds (considered to be equivalent to a single power feed) may be connected to a single segment. For example, a driver with maximum output of 10 mA connects to a 20 cm² segment. If the segment needs 1 mA/cm² to produce the desired light output, then this segment would need 2 power feeds (one from each driver or one each from 2 channels of a multi-channel driver). Alternatively, a 10 cm² segment could be driven by a single driver, but the corresponding power feed can be split into two paths if needed to accommodate other power feeds in the device. Such arrangements can help distribute the power more uniformly over the segment or reduce IR drop. However, in some instances, the same power feed can be used for two or more segments. Segments that share a common power feed cannot be activated independently and will emit in common and are considered as being equivalent to a single segment.

There is an external contact area (also referred to as a contact pad) outside of the encapsulation that is electrically connected to each of the power feeds that are within the encapsulation. Although the Figures show an extension of the power feeds outside of the encapsulation that forms the contact areas, it is also possible to selectively remove encapsulation over the power feeds to make electrical contact through the encapsulation. Controlled power sources are then electrically connected (i.e., by soldering or ACF) to these contact areas to supply power as necessary to the power feeds and segmented electrodes within the encapsulation. Delivering the appropriate amount of power to the contact areas over a suitable period of time will cause the OLED segment to emit light at the desired luminance for that period of time. The power delivered to the external contact pads is determined by a controller or driver. It is very desirable that all of the contact pads for each power feed be located along one side or edge of the substrate.

The location and distribution of the individual power feeds across the surface of the substrate will depend on the design of the OLED segment array. Some power feeds may be located along non-emitting areas (i.e., in the gaps between segments and/or outside edge of the device) while others are located under the electrode segments and in the light path. Depending on the design, some segments may not have not any power feeds located between or below them while other segments have multiple power feeds between or below them.

It is important that the IR drop along the power feeds be similar for all OLED segments without regard to the distance from the external power source or the size of the OLED segment (larger segments require more power for operation than smaller segments). However, IR drop can be minimized by adjusting the width (parallel to the substrate) or height (above the substrate) of the power feed. Thus, in such cases, not all of the power feeds will have the same width and height dimensions, which can vary as a function of their length as well. Moreover, not all of the power feeds may have the same construction. For example, shorter power feeds may be made of a conductive metal oxide but longer power feeds may have an auxiliary electrode or be made of metal like a thin layer of Ag.

If the power feeds are not located within the emission pathway, they may be opaque or transparent as desired. If they are located in the emission pathway, the power feeds should be as transparent as possible. The power feeds may be composed of any electrically conductive material that can be patterned. For example, the power feeds may be made of metal such as silver or copper, conductive metal oxides such as ITO, AZO, IZO, GZO, ZnO, TiN or SnO₂, organic materials such as PEDOT:PSS, CNTs (carbon nanotubes), graphene or conductive particles such as silver, nickel or copper suspended in a polymeric binder (conductive inks) or any combination of these materials. Conductive materials that are inherently opaque (i.e., silver) can be in the form of nanowires or mesh so there are openings within the structure of the power feeds that allow some light to pass or may be thin enough to not be opaque. Ideally, the power feeds should have a resistivity of less than 25 ohms/square and desirably less than of 15 ohm/square.

Desirably, the power feeds are composed of a conductive metal oxide with ITO being particularly preferred. However, ITO is known to have a limited degree of lateral electrical conduction. If necessary, power feeds formed of a conductive metal oxide can have an auxiliary electrode (for example, an overcoat or sublayer of a conductive metal such as metallic silver or aluminum, or a conductive metallic mesh) to help minimize IR drop for part or all of its length

Generally speaking, the conductive material from which the conductive layer or power feeds are composed may have a relatively high refractive index while the surrounding materials can have a different, often substantially lower, refraction. This difference in refractive index at the interface between the conductive materials and neighboring materials can lead to a visible difference in emission or a decrease in emission due to internal light refraction. By matching the index of refraction between the conductive layer or power feeds (or at least, minimizing any mismatch) to other materials in direct contact or by incorporating a refraction-reduction material in the segmented OLED device where the index of refraction of the refraction-reduction material is more similar in magnitude to the refraction index of the conductive layer or power feeds, any visible difference in emission due the presence of the mismatched materials in the light pathway can be eliminated or at least reduced. Ideally, the reflectance difference (DR) between the regions of the transparent substrate where the conductive layer or power feeds are located and the regions of the transparent substrate where the gaps between the power feeds are located is 5% or less. In order to achieve this, it is desirable that the ratio (higher RI/lower RI) of the refractive index RI of the conductive layer or power feed and the refractive index RI of any of the materials in direct contact with the conductive materials is in the range of 1.00 to 1.06. The inclusion of the refraction-reduction material helps make the emission from each segment in the device appear more uniform. It is important that the refraction-reduction material and layers are electrically non-conductive. Note that only the difference in RI is important; it does not matter which material is higher and which is lower.

In order to form a passive capacitor structure with either a conductive layer 20 or power feeds as a lower electrode and to prevent shorting with the overlying electrode segment, the upper surface of these conductive structures are covered with a non-conductive dielectric material that separates them from the electrode segment. The dielectric material for the passive capacitor structure can be an insulating layer 30, which can be patterned or unpatterned as necessary. The insulating layer 30 can also be present outside the overlap area between the conductive structures that serve as the lower passive capacitor structure electrode and the electrode segment that serves as the upper electrode of the passive capacitor structure. In some embodiments, sections of an auxiliary insulating layer 31 may be present. For example, an insulating layer 31 may be used to fill the space between and electrically separate different sections of conductive layer 20, the power feeds and conductive layer, the power feeds or for planarization. Insulating layer 31 may or may not be composed of the same material(s) as insulating layer 30.

The capacitance of the passive capacitor structure formed by the conductive layer 20 or power feeds, insulating layers 30 (and 31 if present), and electrode segment will depend on the composition and thickness of the dielectric insulating layer 30 (and 31 if present) as well the amount of overlap between the capacitor electrodes. Thus, the thickness and composition of the insulation layer 30 (and 31, if present) should be selected according to the overlap so that the passive capacitance, when added to the inherent capacitance of that particular OLED segment, will be sufficient to provide ESD protection.

The insulating layers 30 or 31 should be both transparent and non-light scattering. The insulating material should have an electrical resistance of no less than 1 Mohm (MΩ) and more preferably, no less than 2 Mohms. Because the insulation layer is within the emission pathway, it is desirable that the insulating material should have a ratio of refractive indexes with the conductive materials of the passive capacitor structure electrodes in the range of 1.00 to 1.06. The insulating layer may be polymeric, but is preferably inorganic. Suitable inorganic insulating layers or materials include SiO₂, SiN, SiON, Al₂O₃, TiO₂, etc. and mixtures thereof. The vertical distance should be greater than 0.05 microns to prevent short circuits and no more than 10 microns and ideally in the range of 0.1-1.0 micron in order to maintain a thin device.

When a power feed is located in the lateral spaces between the electrode segments, the electrical contact between the power feed and its electrode segment is typically made to the side of the electrode segment. If the power feed is located below the electrode segment, the electrical connection between the power feed and the overlying segmented electrode is made through a via, which is a hole or pathway in the insulating materials (i.e., the insulating layer 30 or 31) that separate the two. The via runs from the top of the power feed to the bottom or side of the segmented electrode. Ideally, the via connects to the segmented electrode in a location corresponding to a non-emitting area of the segmented OLED. The via can be formed by patterning the overlying insulating material so as to leave at least a portion of the top surface of the power feed exposed or uncovered. Alternatively, the overlying insulating material can be uniformly deposited over the power feeds and the via created by removal of the materials over the desired section of the power feed and thus, exposing the top surface.

The via is filled with electrically conductive material. When the segmented electrode is deposited over the materials, some of the material of the segmented electrode can fill the via to make the connection. Alternatively, the via can be filled first with an electrically conductive material and then the segmented electrode is deposited over the filled via/top surface of the insulating material. In some cases, it may be necessary to treat the power feed, prior to depositing the insulating layer, or a filled via, prior to depositing the segmented electrode, with a material that promotes electrical conductivity through the connection.

The length and area of the via is not critical, but should be sufficient to supply the necessary power to the segmented electrode. The via can be of any shape along the upper surface of the power feed. In particular, it may extend along a length of the power lead. There may be more than one via between the power feed and electrode segment.

There is an array of individual electrode segments located over a common substrate along with any other intervening layer. By “common”, it is meant that all OLED segments in the array share the same substrate and are manufactured together on that substrate as an array. There is a non-emitting lateral gap between the individual segments on all sides (except for the ones located along the outside edge or at the corners of the device) that separates them.

The segmented OLED device is a bottom emitter and the bottom electrode segments are transparent. The transparent electrode segment should transmit as much light as possible, preferably having a transmittance of at least 70% or more desirably at least 80%. However, in some applications (i.e., microcavity devices), the transparent bottom electrode may only be semi-transparent and have partial reflectivity. While the bottom transparent electrode may be made of any conductive materials, metal oxides such as ITO or AZO or thin layers of metals such as Ag are preferable. In some cases, there may be an auxiliary electrode to help distribute charge more uniformly across the area of the transparent electrode. Ideally, the electrode segments should have a resistivity of less than 25 ohms/square and desirably in the range of 10-23 ohm/square.

In some embodiments, there is a pixel definition layer (PDL) which separates parts of one OLED segment from another or along the outside perimeter of the array. The PDL separates the electrode segments from being in electrical contact, defines the outside edge of the array and can be used to restrict organic layers to a single OLED segment. In some cases, it can be used to partially cover the electrode segment to prevent light-emission in the PDL areas (for example, in areas where the via is located along the edge of the electrode segment). In other cases where there is no PDL layer in the gap between the electrode segments, there still may PDL located along the outside perimeter of the array. The PDL should be insulating (electrically non-conductive).

In some embodiments, the PDL in the gap between the bottom electrode segments will have approximately the same thickness as the electrode segments. This will create a relatively flat surface for depositing the overlying layers. In other embodiments, the PDL will be thicker than the electrode segments and so a section of the PDL will extend past the upper surface of the electrode segment, either in the gaps or along the outside edge of the array. In some instances, the extended portion of the PDL will also cover some part of the upper surface of the electrode surface. In such cases, the PDL may cause light piping or light guiding which would be undesired. To reduce light piping, absorbing dyes may be added to the PDL Alternatively, the PDL layer material may be opaque or black.

Suitable PDL materials may be polymeric or inorganic. Some examples of a suitable polymeric PDL include acrylic and polyimide polymers. Some examples of a suitable inorganic PDL include SiO₂, SiN and SiON. Ideally, the PDL layer should be no more than 5 microns thick and desirably in the range of 0.2-3.0 microns.

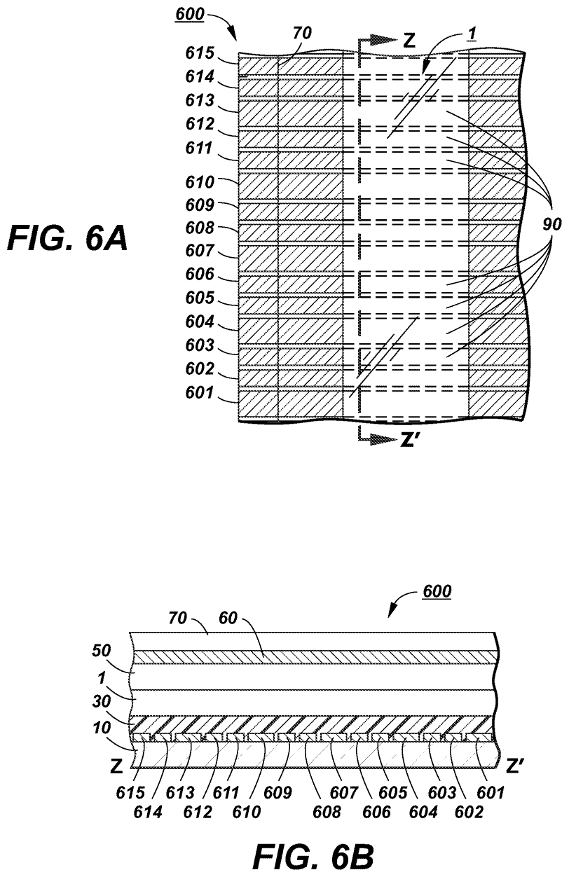

FIG. 7 shows a typical composition of OLED layer types for light emission in an example OLED 1000. There will be one or more light-emitting layers with multiple auxiliary layers to help promote and control the movement of charge between the electrodes during light emission. In this particular example, the bottom electrode segment is an anode and the top electrode is a cathode.

Over the transparent electrode segment 514, there may be a hole-injection layer (HIL, Layer 501) as needed. The purpose of an HIL is to manage the transport of holes to the organic layers from the anode. Suitable hole-injection materials are well-known and commonly used. These layers may be mixtures of such materials and may contain dopants to modify their properties. Since it is non-light emitting, it does not contain emitting materials. There is generally only one HIL present. The choice of appropriate materials is not critical and any may be selected based on their performance. One example of a suitable HIL material is HAT-CN.

Over the HIL (Layer 501) is located a hole-transport layer (HTL, Layer 502). The purpose of an HTL is to manage the transport of holes from HIL to the light-emitting layers above. Suitable hole-transport materials are well-known and commonly used. These layers may be mixtures of such materials and may contain dopants to modify their properties. Since it is non-light emitting, it does not contain emitting materials. There may be multiple HTLs present. The choice of appropriate materials is not critical and any may be selected based on their performance. One example of a suitable HTL is NPB.

Over the HTL (Layer 502) is located an exciton-blocking layer (EBL; Layer 503) as needed. Light-emitting layers emit via the formation of excitons which in some cases, have sufficient lifetime to diffuse away from the site of its formation. The purpose of an EBL is to confine the excitons to the LEL to maximize light emission. Suitable exciton-blocking materials are well-known and commonly used. These layers may be mixtures of such materials and may contain dopants to modify their properties. Since it is non-light emitting, it does not contain emitting materials. There may be multiple EBLs present. The choice of appropriate materials is not critical and any may be selected based on their performance. One example of a suitable EBL is mCP.

Over the EBL (Layer 503) is located a first light-emitting layer or unit (LEL1; Layer 504). A light-emitting layer (LEL), which is a single layer, generally contains one or more non-emitting host compounds and one or more light-emitting dopants. Host materials and fluorescent, phosphorescent and TADF light-emitting dopants suitable for use in light-emitting layers or units are well-known and commonly used. A light-emitting unit, as previously defined, could also be used for emission. The choice of appropriate materials is not critical and any may be selected based on their performance and emission characteristics.

Over LEL1 (Layer 504) is located a hole-blocking layer (HBL; Layer 505) as needed. Light-emitting layers emit via the formation of excitons which in some cases, are not formed sufficiently fast before holes migrate towards the cathode. The purpose of an HBL is to confine the holes to the LEL to maximize light emission. Suitable hole-blocking materials are well-known and commonly used. These layers may be mixtures of such materials and may contain dopants to modify their properties. Since it is non-light emitting, it does not contain emitting materials. There may be multiple HBLs present. The choice of appropriate materials is not critical and any may be selected based on their performance. One example of a suitable HBL is SF3-TRZ.

Over the HBL (Layer 505) is located a charge generating layer (CGL; Layer 506). CGLs (sometimes also referred to as connector or intermediate layers) are located between the individual OLED light-emitting units and typically consist of multiple layers. This is because the CGLs are structured so that electrons and holes are generated upon voltage application, and injected to the adjacent organic emissive layers. Hence, the use of a CGL can possibly convert one injected electron to multiple photons, allowing for higher luminance. In particular, it is desirable that a CGL is located between each light-emitting unit within the stack. However, it is not necessary for a light-generating unit to have an adjacent CGL on both sides. The OLED light-generating units on the top and bottom of the stack will generally have only one adjacent CGL. There is typically no need to use a CGL between a light-emitting unit and one of the top or bottom electrodes, although a CGL could be used if desired.

Many different kinds of CGLs have been proposed and may be used in the OLED stack. For example, see U.S. Pat. No. 7,728,517 and US2007/0046189. For the formation of a CGL, an n-p semiconductor heterojunction, which is located at the interface of n-type and p-type layers, is typically needed for the charge generation. Thus, CGLs will have two or more layers. For example, n-doped organic layer/transparent conductive layer, n-doped organic layer/insulating material, n-doped organic material layer/metal oxide layer, and n-doped organic material layer/p-doped organic material layer have all been reported. A desirable metal oxide for CGLs is MoO₃. In some instances, the n-layer and p-layer may be separated by a thin intermediate layer. Often, the CGL is arranged so that the n-layer is closer to the anode and the p-layer is closer to the cathode.

One desirable formulation for a CGL has three layers; an electron-transport material doped with a n-dopant (for example, Li), a thin intermediate layer of the same (but undoped) electron-transport material, and a hole-transport material doped with a p-dopant. Another desirable formulation for a CGL would have the same type of doped ETL, with an interlayer of a different electron-transport material and an electron deficient hole-injection material such as HAT-CN. Another desirable formulation for a CGL would have an undoped ETL layer, a layer of Li or Ca, an interlayer of the same or different electron-transport material and an electron deficient hole-injection material or a hole-transport material doped with a p-dopant.

Suitable electron-transport and hole-injection or transport materials, along with n-dopants and p-dopants suitable for use in CGLs are well-known and commonly used. The materials may be organic or inorganic. The choice of appropriate materials is not critical and any may be selected based on their performance. The thickness of the CGL should desirably be in the range of 200-450 Å, although in some examples, a thinner CGL may be in the range of 100-200 Å. In many instances, the CGL will have an ETL or HBL on the anode side and an HTL or EBL on its cathode side to help improve charge transport and help separate the charge-generating dopants (if present) from the LEL in the light-emitting units. There may be multiple such layers and may be doped or undoped as desired.

Over the CGL (Layer 506), is located a second light-emitting layer or unit (LEL2; Layer 507) representing the second stack of the OLED device. In FIG. 7, the two LELs (Layers 504 and 507) are separated by a CGL (Layer 506) and so, the OLED stack in FIG. 7 is a “two-stack” (or double-stacked) OLED. There may be one or more HTLs (doped or undoped) between the CGL (Layer 506) and LEL2 (Layer 507). LEL2 may emit the same color as LEL1 or a different color.

Over LEL2 (Layer 507) is located at least one HBL (Layer 508) similar to that described as Layer 505.

Over the HBL (Layer 508) is located an electron-transport layer (ETL; Layer 509). The purpose of the ETL is to manage the transport of electrons from the EIL to the light-emitting layers below. Suitable electron-transport materials are well-known and commonly used. These layers may be mixtures of such materials and may contain dopants to modify their properties. Since it is non-light emitting, it does not contain emitting materials. There may be multiple ETLs present. The choice of appropriate materials is not critical and any may be selected based on their performance. One example of a suitable ETL is TPBI.

Over the ETL (Layer 509) is located an electron-injecting layer (EIL; Layer 510) as needed. The purpose of the EIL is to manage the transport of electrons to the organic layers from the cathode. Suitable electron-injection materials are well-known and commonly used. These layers may be mixtures of such materials and may contain dopants to modify their properties. Since it is non-light emitting, it does not contain emitting materials. There is generally only one EIL present. The choice of appropriate materials is not critical and any may be selected based on their performance. One example of a suitable EIL material is LiF.

Over the organic layers for light emission (50; Layers 501-510 in FIG. 7), there is a top electrode 60 which in FIG. 7 is a cathode. It is desirably composed of a thicker layer of metal or metal alloy such as Al, Ag, Mg/Al, Mg/Ag and the like. The top electrode may be deposited by any known technique. The top electrode may be patterned in non-emissive areas, but generally is deposited uniformly over the emission area. There needs to be contact area (contact pad) that is external to the encapsulation that is electrically connected to the top electrode within the encapsulation for external power supply. Some examples of suitable materials for the top electrode are Al, Al/Mg, Ag/Mg and Ag.

There may be optional protective or spacing layers (Layer 511 in FIG. 7) over the top electrode to prevent damage during encapsulation. These may be small molecule organic, polymeric or inorganic materials. Organic materials are preferred.

Over the reflective cathode and any optional protective layers, if present, is deposited or placed encapsulation 70. At a minimum, the encapsulation should fully cover the light-emitting area on the top and sides and is in direct contact with the substrate. The encapsulation should be impervious to air and water penetration. It may be transparent or opaque. It should not be electrically conductive. It may be formed in-situ or added as a separate pre-formed sheet along with provisions for sealing the side edges.

An example of in-situ formation would be thin-film encapsulation. Thin-film encapsulation involves the deposition of multiple layers with alternative layers of inorganic materials and polymeric layers until the desired degree of protection is achieved. Formulations and methods to form thin-film encapsulation are well known and any can be used as desired.

Alternatively, encapsulation may be provided using a pre-formed sheet or cover slip which is attached over at least a sealing area and enclosed area. The pre-formed sheet may be rigid or flexible. It could be made of glass (including flexible glass), metal or organic/inorganic barrier layers. It should have a thermal expansion coefficient that is close to the substrate to achieve a more robust connection. Pre-formed encapsulation sheets may need to be attached over the sealing area using air- and water-proof adhesives such as silicon or epoxy adhesives or by thermal means such as ultrasonic welding or glass frit welding, which may require additional sealants such as solder or glass frit. The side and bottom edges of the cover slip can be specially designed to have better fit to the sealing area or promote a better seal. The cover slip and sealing area may be designed together so that they fit or lock partially in place before the seal is formed. Moreover, the cover slip may be pretreated to promote better adhesion to the sealing area.

For some applications, an increased degree of encapsulation is necessary. This can be accomplished by providing an additional metal foil encapsulation (Layer 513) which is attached over the encapsulation 70 by a pressure-sensitive adhesive (Layer 512). Not only does the use of a metal foil provide robust encapsulation, it also acts as a heat sink to prevent excessive heating which is deleterious to OLED devices.

For many applications, a single stack OLED device can provide sufficient emission for the intended purpose. For some applications, more luminance is required than can be provided by a single OLED stack. In such cases, two (as shown for FIG. 7) or more stacks will be required. Generally speaking, adding an OLED stack (i.e., two units instead of one) will double the luminance produced, although the power required is also doubled. Three-stack OLEDs will produce 3× the luminance but require 3× the power and so forth. In the segmented OLED device of the invention, as many stacks as necessary to produce the desired amount of luminance can be added; the only limitation being the increased voltage necessary to drive the device. Desirably, there are at least two stacks and as many as six stacks in the segmented OLED device.

Another method of increasing luminance, particularly when single color emission is desired, from an OLED is to incorporate the microcavity effect. To form a microcavity, one electrode is reflective and the other is semi-transparent so light is reflected internally. Depending on the distance between the two electrodes, interference will occur and some wavelengths of light will be eliminated or reduced, while other wavelengths will be enhanced. The microcavity effect can be used for the OLED segments of the device.

All OLED segments can emit white or multimodal light and color filters used to create the desired color of emission of each particular segment. While the various individual LELs or units within the segmented OLED device are not limited to providing the same color, some applications require monochromatic emission. For example, for many automotive tail-light applications, all LELs or units should produce red light. It should be noted that although different LELs or units all might produce the same color of light, it is not necessary that all have identical emission spectrums; some may have a different proportion of certain wavelengths from another (i.e., one unit produces a spectrum with more short red wavelengths while another produces more longer red wavelengths).

One method for making a bottom-emitting segmented OLED device with an array of OLED segments, where at least one OLED segment comprises a passive capacitor structure to increase the total capacitance, would comprise, in order, the steps of:
1) Depositing a layer of transparent electrically conductive material on a transparent substrate, where the conductive material will form a lower electrode of a passive capacitor structure;
2) Depositing a transparent electrically insulating material over the conductive layer, where the insulating material will form the dielectric in a passive capacitor structure;
3) Patterning transparent electrode segments and electrically conductive power feeds over the insulating material such that there will be one power feed for each electrode segment and where at least one overlying electrode segment overlaps at least part of the underlying conductive layer; where the overlap between the conductive layer and electrode segment, which are separated by the insulating material of step 2, forms a passive capacitor structure;
4) Depositing a pixel definition material in the lateral spaces between the electrode segments, between the power feeds and between the electrode segments and power feeds for other electrode segments;
5) Depositing organic layers for light emission over the upper surface of the electrode segments;
6) Depositing a common top electrode over the organic layers to complete an OLED segment comprising the bottom electrode segment, organic layers and top electrode; and
7) Forming encapsulation over the array of OLED segments.

Another method for making a bottom-emitting segmented OLED device with an array of OLED segments, where at least one OLED segment comprises a passive capacitor structure to increase the total capacitance, would comprise, in order, the steps of:
1) Patterning an electrically conductive transparent material and electrically conductive power feeds on the transparent substrate so that the power feeds are not in contact with the conductive material and filling the lateral spaces between the conductive material and power feeds with an electrically insulating material, where at least some of the conductive material will form the lower electrode of a passive capacitor structure,
2) Depositing a transparent electrically insulating material over the conductive layer and power feeds, where the insulating material will form the dielectric in a passive capacitor structure;
3) Forming vias in the insulating layer over the power feeds;
4) Patterning transparent electrode segments over the insulating material such that there will be one electrode segment, connected to one power feed through the vias for each OLED segment such that at least one overlying electrode segment overlaps at least part of the underlying conductive layer so that the overlap between the conductive layer and electrode segment, together with the insulating material of step 2, forms a passive capacitor structure;
5) Depositing a pixel definition layer in the lateral spaces between the electrode segments;
6) Depositing organic layers for light emission over at least the upper surface of the electrode segments;
7) Depositing a common top electrode over the organic layers to complete an OLED segment comprising the bottom electrode segment, organic layers and top electrode; and
8) Forming encapsulation over the array of OLED segments.

Some useful variations in any of the above methods include:
patterning the conductive layer so that is common to all electrode segments;
patterning the conductive layer so that it will overlap with at least two electrode segments;
patterning the conductive layer so that it will overlap less than all of the electrode segments so that some OLED segments do not have a passive capacitor structure.

Another method for making a bottom-emitting segmented OLED device with an array of OLED segments, where at least one OLED segment comprises a passive capacitor structure to increase the total capacitance, would comprise, in order, the steps of:
1) Patterning electrically conductive power feeds on the transparent substrate and filling the lateral spaces between the power feeds with an electrically insulating material, where at least some of the power feeds act as a conductive layer that will form the lower electrode of a passive capacitor structure;
2) Depositing a transparent electrically insulating material over the power feeds, where the insulating material will form the dielectric in a passive capacitor structure;
3) Forming vias in the insulating layer over the power feeds;
4) Patterning transparent electrode segments over the insulating material such that there will be one electrode segment, connected to one power feed through a via for each OLED segment such that the bottom electrode segment of one OLED segment overlaps at least part of one section of the underlying conductive layer that is connected to another OLED segment so that the overlap between the conductive layer connected to another OLED segment and bottom electrode segment of the one OLED segment, together with the insulating material of step 2, forms a passive capacitor structure;
5) Depositing a pixel definition layer in the lateral spaces between the electrode segments;
6) Depositing organic layers for light emission over at least the upper surface of the electrode segments;
7) Depositing a common top electrode over the organic layers to complete an OLED segment comprising the bottom electrode segment, organic layers and top electrode; and
8) Forming encapsulation over the array of OLED segments.

Some useful variations in the above method include:
patterning the conductive layer so that it will overlap with less than all of the electrode segments so that some OLED segments do not have a passive capacitor structure.
where the area of the OLED segment with the passive capacitor is less than 1 cm².
where the area of the OLED segment with the passive capacitor is at least 0.05 cm².
the area of the overlap between the conductive layer section(s) and the bottom electrode segment increases the total capacitance of the OLED segment by at least 0.2 nF.
the area of the overlap between the electrode segment and conductive layer is at least 30% or greater of the electrode segment.

Some desirable physical and performance characteristics for the bottom-emitting segmented OLED device include:
Brightness: 2,000-20,000 cd/m²;
Number of OLED Segments: >200 (can be mix of sizes and shapes);
Active Area: 25 cm² or greater;
Segment Size: <1 cm² and most preferably <0.5 cm²;
Current density for 2000 cd/m²: 13 mA/cm² (2-stack), 4.3 mA/cm² (6-stack);
Current density for 5000 cd/m²: 32 mA/cm² (2-stack), 9 mA/cm² (6-stack);
Current Density for 10000 cd/m²: 25 mA/cm² (6-stack);
Current Density for 20000 cd/m²: 50 mA/cm² (6-stack);
Non-emitting gap: <1 mm, preferably <700 μm, and most preferable <200 μm; and

All electrical contact areas (bottom and top electrodes) outside the encapsulation are located along only one edge of device.

The above description describes a number of different embodiments. Individual features from any of the embodiments may be combined without limitation except when mutually exclusive.

In the above description, reference is made to the accompanying drawings that form a part hereof, and in which are shown by way of illustration specific embodiments which may be practiced. These embodiments are described in detail to enable those skilled in the art to practice the invention, and it is to be understood that other embodiments may be utilized and that structural, logical and electrical changes may be made without departing from the scope of the present invention. The description of any example embodiments is, therefore, not to be taken in a limiting sense. Although the present invention has been described for the purpose of illustration, it is understood that such detail is solely for that purpose and variations can be made by those skilled in the art without departing from the spirit and scope of the invention.

### Modeling and Experimental Results

ESD reliability testing of segmented OLED devices used in automotive applications is grouped into different categories or models, corresponding to scenarios the device can be exposed to. The more challenging scenario for OLED devices is the ESD human body model (HBM), which represents when charge from an operator is transferred to the device, typically through a finger. HBM ESD reliability testing is governed by the JEDEC-JS-001-2017 testing standard.

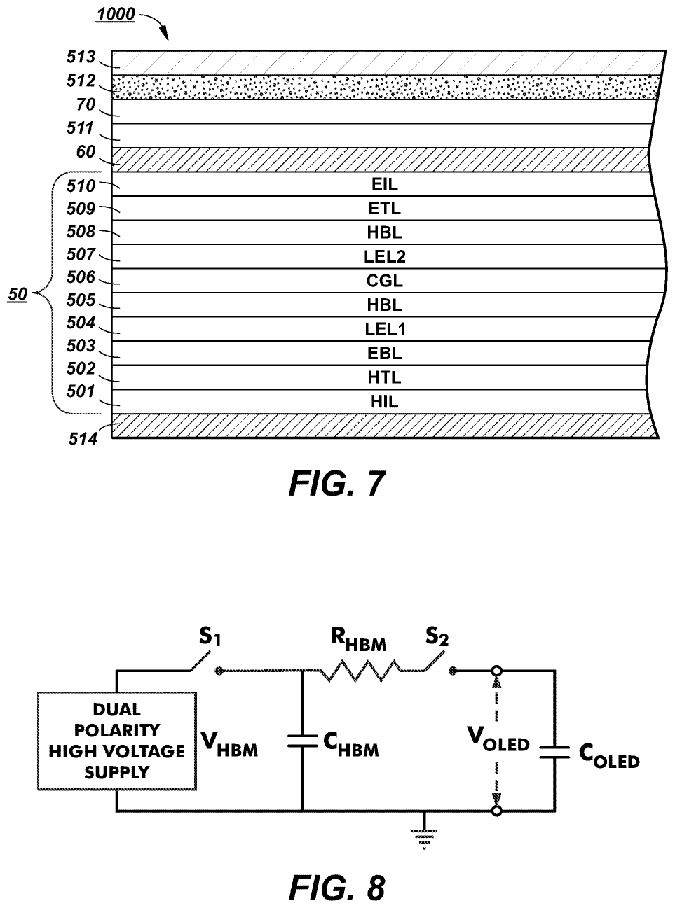

In FIG. 8, a test circuit with a 0.1 nF capacitor (C_{HBM}) is charged to a standard voltage level (V_{HBM}) by a dual polarity high voltage supply when switch S1 is closed, and then discharged to the test OLED device through a 1.5 kΩ resistor (R_{HBM}) when switch S2 is closed. The HBM V_{HBM} standard classification levels are listed in Table 1, with the level chosen determining the amount of charge the device is exposed to during the test.

TABLE 1
ESD Sensitivity Classification for HBM Test

| Class | V_{HBM} | |
|---|---|---|
| 0 | 0-250 | V |
| 1A | 250-500 | V |
| 1C | 1000-2000 | V |
| 2 | 2000-4000 | V |
| 3A | 4000-8000 | V |
| 3B | >8000 | V |

When charge is transferred to the OLED, a voltage (V_{OLED}) forms, with a greater amount of charge transfer leading to higher voltages. V_{OLED} can be estimated by performing a simple charge balance using the HBM test parameters and OLED capacitance (C_{OLED}) as follows, where Q is the charge in Coulombs:

$${Q}_{final} = {Q}_{initial} \qquad ( 1 a )$$

$${V}_{OLED} \times ( {C}_{OLED} + {C}_{HBM} ) = {C}_{HBM} \times {V}_{HBM} \qquad ( 1 b )$$

$${V}_{OLED} = ( {C}_{HBM} \times {V}_{HBM} ) / ( {C}_{OLED} + {C}_{HBM} ) \qquad ( 1 c )$$

No degradation or damage will occur to the OLED if V_{OLED} stays below a certain voltage limit (V_{LIM}) which is a characteristic of the organic stack and typically determined experimentally. If V_{LIM} is expected to be reached under the test conditions, additional elements such as a passive capacitor structure can be incorporated into the design to mitigate the voltage for which the OLED is exposed.

As shown in Tables 2a and 2b, V_{OLED} was calculated from Equation 1 for different OLED segment areas and number of red automotive organic stacks at V_{HBM} test conditions of 2 kV and 8 kV. Note that in this experiment, the capacitance per unit area of a two-stack red automotive OLED device was 21.7 nF/cm², and a similar six-stack device was 6.8 nF/cm². All of the examples are simple bottom-emitting OLEDs and none include a passive capacitor structure.

TABLE 2a
Calculated V_{OLED} for 2-stack OLED Segments

| OLED Area | C_{OLED} | V_{OLED} | V_{OLED} |
|---|---|---|---|
| (cm²) | (nF) | (V_{HBM} = 2 kV) | (V_{HBM} = 8 kV) |
| 0.05 | 1.09 | 169 | 675 |
| 0.10 | 2.17 | 88 | 352 |
| 0.17 | 3.69 | 53 | 211 |
| 0.25 | 5.43 | 36 | 145 |
| 0.38 | 8.25 | 24 | 96 |

TABLE 2b
Calculated V_{OLED} for 6-stack OLED Segments

| OLED Area | C_{OLED} | V_{OLED} | V_{OLED} |
|---|---|---|---|
| (cm²) | (nF) | (V_{HBM} = 2 kV) | (V_{HBM} = 8 kV) |
| 0.05 | 0.34 | 456 | 1822 |
| 0.10 | 0.68 | 257 | 1028 |
| 0.17 | 1.15 | 160 | 639 |
| 0.25 | 1.70 | 111 | 446 |
| 0.38 | 2.58 | 75 | 299 |

If the calculated V_{OLED} exceeds the V_{LIM} of the organic stack, device damage from ESD is likely to occur and additional protection is required. In the devices of Tables 2a-2b, it is been experimentally determined that all of the 0.38 cm² two-stack red automotive OLED segments pass the 2 kV V_{HBM} ESD test, but many of the 0.17 cm² segments do not, suggesting that V_{LIM} for this stack is between 24 and 53 V. The data suggests that V_{LIM} is approximately 40 V and conservatively 120 V for the two and six-stack OLED respectively.

For additional capacitive protection, the C_{PASSIVE} required can be calculated as follows:

$${Q}_{final} = {Q}_{initial} \qquad ( 2 a )$$

$${V}_{LIM} \times ( {C}_{OLED} + {C}_{PASSIVE} + {C}_{HBM} ) = {C}_{HBM} \times {V}_{HBM} \qquad ( 2 b )$$

$${C}_{PASSIVE} = ( {C}_{HBM} \times {V}_{HBM} ) / {V}_{LIM} - {C}_{OLED} - {C}_{HBM} \qquad ( 2 c )$$

Since the V_{LIM} for each OLED segment is dependent on the OLED formation, it is useful to assume a range of V_{LIM} and calculate the required C_{PASSIVE} (if any) from Equation 2c. The C_{PASSIVE} required over a range of V_{LIM} for different segment areas for two- and six-stacks at 2 and 8 kV V_{HBM} is shown in Tables 3a-3b and 4a-4b respectively. Note that negative values of C_{PASSIVE} suggest that no ESD protection is required for these particular OLED segments and are included here only to indicate how close a particular scenario is to device damage.

TABLE 3a
C_{PASSIVE} required for 2-Stack OLED Segment for V_{HBM} = 2 kV

| OLED | | | | |
|---|---|---|---|---|
| Area | C_{PASSIVE} (nF) | C_{PASSIVE} (nF) | C_{PASSIVE} (nF) | C_{PASSIVE} (nF) |
| (cm²) | V_{LIM} = 20 V | V_{LIM} = 40 V | V_{LIM} = 80 V | V_{LIM} = 120 V |
| 0.05 | 8.82 | 3.82 | 1.32 | 0.48 |
| 0.10 | 7.73 | 2.73 | 0.23 | −0.60 |
| 0.17 | 6.21 | 1.21 | −1.29 | −2.12 |
| 0.25 | 4.48 | −0.53 | −3.03 | −3.68 |
| 0.38 | 1.65 | −3.35 | −5.85 | −6.68 |

TABLE 3b
C_{PASSIVE} required for 2-Stack OLED Segment for V_{HBM} = 8 kV

| OLED | | | | |
|---|---|---|---|---|
| Area | C_{PASSIVE} (nF) | C_{PASSIVE} (nF) | C_{PASSIVE} (nF) | C_{PASSIVE} (nF) |
| (cm²) | V_{LIM} = 20 V | V_{LIM} = 40 V | V_{LIM} = 80 V | V_{LIM} = 120 V |
| 0.05 | 38.82 | 18.82 | 8.82 | 5.48 |
| 0.10 | 37.73 | 17.73 | 7.73 | 4.40 |
| 0.17 | 36.21 | 16.21 | 6.21 | 2.88 |
| 0.25 | 34.48 | 14.48 | 4.48 | 1.14 |
| 0.38 | 31.65 | 11.65 | 1.65 | −1.68 |

For the above two-stack OLED device at a V_{HBM} of 2 kV (which has a V_{LIM} of 40 V), it is estimated that no additional capacitance would be required for the 0.38 and 0.25 cm² segment sizes, although the latter of the two areas would be close to the limit. At these same conditions, the 0.17, 0.10, and 0.05 cm² segments would require a C_{PASSIVE} of 1.21 nF, 2.73 nF, and 3.82 nF per segment respectively. Higher V_{LIM} values would naturally reduce the C_{PASSIVE} required. For the two-stack OLED at 8 kV V_{HBM}, ESD protection would be required for most of the conditions explored (Table 3b).

TABLE 4a
C_{PASSIVE} required for 6-Stack OLED Segment for V_{HBM} = 2 kV

| OLED | C_{PASSIVE} | C_{PASSIVE} | C_{PASSIVE} | C_{PASSIVE} | C_{PASSIVE} | C_{PASSIVE} |
|---|---|---|---|---|---|---|
| Area | (nF) | (nF) | (nF) | (nF) | (nF) | (nF) |
| (cm²) | V_{LIM} = 40 V | V_{LIM} = 80 V | V_{LIM} = 120 V | V_{LIM} = 160 V | V_{LIM} = 200 V | V_{LIM} = 240 V |
| 0.05 | 4.56 | 2.06 | 1.23 | 0.81 | 0.56 | 0.39 |
| 0.10 | 4.22 | 1.72 | 0.89 | 0.47 | 0.12 | 0.06 |
| 0.17 | 3.75 | 1.25 | 0.41 | 0.0 | −0.25 | −0.42 |
| 0.25 | 3.21 | 0.71 | −0.13 | −0.55 | −0.80 | −0.96 |
| 0.38 | 2.32 | −0.18 | −1.01 | −1.43 | −1.68 | −1.84 |

TABLE 4b
C_{PASSIVE} required for 6-Stack OLED Segment for V_{HBM} = 8 kV

| OLED | C_{PASSIVE} | C_{PASSIVE} | C_{PASSIVE} | C_{PASSIVE} | C_{PASSIVE} | C_{PASSIVE} |
|---|---|---|---|---|---|---|
| Area | (nF) | (nF) | (nF) | (nF) | (nF) | (nF) |
| (cm²) | V_{LIM} = 40 V | V_{LIM} = 80 V | V_{LIM} = 120 V | V_{LIM} = 160 V | V_{LIM} = 200 V | V_{LIM} = 240 V |
| 0.05 | 19.56 | 9.56 | 6.23 | 4.56 | 3.56 | 2.89 |
| 0.10 | 19.22 | 9.22 | 5.89 | 4.22 | 3.22 | 2.56 |
| 0.17 | 18.75 | 8.75 | 5.41 | 3.75 | 2.75 | 2.08 |
| 0.25 | 18.21 | 8.21 | 4.87 | 3.21 | 2.21 | 1.54 |
| 0.38 | 17.32 | 7.32 | 3.99 | 2.32 | 1.32 | 0.68 |

For the six-stack OLED and V_{HBM} of 2 kV (Table 4a), no C_{PASSIVE} would be required for the 0.38 and 0.25 cm² OLED segments above a V_{LIM} of 120 V, although the latter would be close to the limit. At those conditions, the six-stack 0.17, 0.10 and 0.05 cm² OLED segments are calculated to need C_{PASSIVE} of 0.41 nF, 0.89 nF, and 1.23 nF per segment, respectively. For the 0.25 cm² segment, a C_{PASSIVE} of 0.71 nF would be required per segment at a V_{LIM} of 80 V. Higher V_{LIM} values would of course reduce the C_{PASSIVE} required for the OLED segment. For the six-stack OLED segment at 8 kV V_{HBM}, ESD protection would be required for all segment sizes and V_{LIM} conditions explored (Table 4b).

In this experiment, a 6-stack OLED formulation is representative of a practical OLED formulation with a relatively low inherent capacitance (C_{OLED}=6.8 nF/cm²). It has an estimated V_{LIM} of 120 V. It is clear that the smaller OLED segments with the lower inherent capacitance will experience the highest voltages from ESD exposure. For example, a 6-stack 0.05 cm² segment will experience 456 V from V_{HBM}=2 kV and 1822 V when V_{HBM}=8 kV (see Table 2b). This is well above V_{LIM} for this OLED formulation. In order avoid ESD damage, the voltage experienced by a 0.05 cm² segment with a 6-stack segment, assuming a V_{LIM} of 120 V, the minimum amount of capacitance that would need to be supplied by the passive capacitor structure would be about 1.23 nF when V_{HBM}=2 kV (see Table 4a). Likewise, a 2-stack formulation, with an inherent capacitance of 21.7 nF/cm² and a V_{LIM} of less than 60 V, the minimum amount of capacitance that would be need to supplied by the passive capacitor structure would be 1.32 nF when V_{HBM}=2 kV (see Table 3a).

Based on the above, it is desirable that the addition of passive capacitors structure(s) of an OLED segment increases the total capacitance compared to the OLED segment without the passive capacitor structures in order to maintain V_{LIM} below a threshold. Since the capacitance of the passive capacitor structure(s) depends directly on the overlap between the common conductive layer and the bottom electrode of the OLED segment, it is desirable that overlap provides at least a 0.2 nF increase in total capacitance of an OLED segment and more desirably, at least a 0.4 nF increase, or most desirably, at least a 1.0 nF increase.

Parts List

| | |
|---|---|
| Z-Z′ | Sectioning Plane/Directional Line |
| 1′-7′ | OLED segments |
| 1-7 | Bottom Segmented Electrode of corresponding OLED |
| | segment |
| 15 | Power Feed for Segmented Electrode 1 |
| 25 | Power Feed for Segmented Electrode 2 |
| 35 | Power Feed for Segmented Electrode 3 |
| 45 | Power Feed for Segmented Electrode 4 |
| 55 | Power Feed for Segmented Electrode 5 |
| 65 | Power Feed for Segmented Electrode 6 |
| 75 | Power Feed for Segmented Electrode 7 |
| 10 | Common Transparent Substrate |
| 20 | Conductive Layer |
| 22, 24, 26 | Conductive Layer Sections |
| 30, 31 | Insulating Layer |
| 32 | Via |
| 40 | Pixel Definition Layer between Segmented Electrodes |
| 50 | Organic Layers for Light Emission |
| 60 | Top Electrode |
| 70 | Encapsulation |
| 80 | Non-Light Emitting Gaps between OLED Segments |
| 90 | Overlap between Conductive Layer and Bottom |
| | Electrode Segment |
| 95 | Control Circuit |
| 100-400 | Segmented OLED Devices with 5 OLED Segments |
| 500 | Segmented OLED Device with 7 OLED segments |
| 600 | Segmented OLED Device with Multiple Conductive |
| | Layer Sections |
| 601-615 | Conductive Layer Sections |
| 1000 | OLED Device |
| 501 | HIL |
| 502 | HTL |
| 503 | EBL |
| 504 | LEL1 |
| 505 | HBL |
| 506 | CGL |
| 507 | LEL2 |
| 508 | HBL |
| 509 | ETL |
| 510 | EIL |
| 511 | Optional Protection Layer |
| 512 | Pressure Sensitive Adhesive |
| 513 | Metal Foil Encapsulation/Heat Sink |
| 514 | Bottom Electrode Segment |
| C_{HBM} | Test Circuit Capacitor |
| C_{OLED} | Capacitance of Associated OLED Structure in an OLED |
| | Segment |
| C_{O1}′-C_{O5}′ | Capacitances of OLED Structures in OLED Segments 1′-5′ |
| C_{PASSIVE} | Capacitance of Associated Passive Capacitor Structure |
| | in an OLED Segment |
| C_{P1}′-C_{P5}′ | Capacitances of Passive Capacitor Strucctures |
| R_{HBM} | Test Circuit Resistor |
| S₁ | First Switch |
| S₂ | Second Switch |
| V_{HBM} | Standard Voltage Level |
| V_{OLED} | OLED Voltage |

1. A segmented bottom-emitting OLED device comprising an array of multiple OLED segments arranged on a common transparent substrate, where the array forms an emitting area where each OLED segment is separated by a non-emitting gap; wherein each OLED segment is defined by a transparent bottom electrode segment, organic layers for light emission, and a top electrode;
wherein between the bottom electrode segment and the substrate in at least one OLED segment, there is a transparent insulating layer that is closer to the bottom electrode segment and a transparent conductive layer that is closer to the substrate, such that the area of overlap between the bottom electrode and the conductive layer forms an associated passive capacitor structure, where the bottom electrode of the OLED segment is the upper electrode of the passive capacitor structure, the insulating layer is the dielectric of the passive capacitor structure, and the conductive layer is the lower electrode of the passive capacitor structure.

2. The OLED device of claim 1 where the conductive layer is patterned.

3. The OLED device of claim 2 where the conductive layer is patterned into two or more sections that are electrically isolated from one another.

4. The OLED device of claim 3 where in at least one OLED segment, the area of the overlap between the conductive layer section(s) and the bottom electrode segment increases the total capacitance of the OLED segment by at least 0.2 nF.

5. The OLED device of claim 3 where in at least one OLED segment, the area of the overlap between the conductive layer section(s) and the bottom electrode segment is 30% or more of the area of the bottom electrode segment.

6. The OLED device of claim 3 where, in addition to those OLED segments with an associated passive capacitor structure, the bottom electrode segment of at least one different OLED segment in the array does not have any overlap with a conductive layer section so that no passive capacitor structure is associated with the at least one different OLED segment.

7. The OLED device of claim 6 where the size of the at least one different OLED segment without the passive capacitor structure is 1.0 cm² or more.

8. The OLED device of claim 1 wherein the bottom electrode of each OLED segment in the array is electrically connected to a dedicated power feed which controls the light emission, where the power feeds are arranged laterally between the bottom electrode segments and are electrically isolated from other power feeds and any independent electrode segments.

9. The OLED device of claim 3 wherein the bottom electrode segment of each OLED segment in the array is electrically connected to a single power feed which controls the light emission, wherein the power feeds are arranged laterally between the conductive layer sections and are electrically isolated from other power feeds and the conductive layer sections as well as being electrically isolated by the insulating layer from the bottom electrode segments of any independent OLED segments.

10. The OLED device of claim 9 further including at least one power feed arranged to pass beneath at least one bottom electrode segment in the emission area of an independent OLED segment.

11. The OLED device of claim 10 where any dedicated power feed arranged to pass beneath at least one bottom electrode segment in the emission area of an independent OLED segment are connected to their corresponding bottom electrode segments through vias in the insulating layer.

12.-14. (canceled)

15. A segmented bottom-emitting OLED device compromising an array of multiple OLED segments arranged on a common transparent substrate, where the array forms an emitting area where each OLED segment is separated by a non-emitting gap; wherein each OLED segment is defined by a transparent bottom electrode segment, organic layers for light emission, and a top electrode;
wherein the bottom electrode segment of each OLED segment in the array is electrically connected to a single power feed which controls the light emission from each OLED segment wherein the power feeds are electrically isolated from other power feeds as well as being electrically isolated by an insulating layer from the bottom electrode segments wherein at least a multiple of power feeds of the OLED segments are arranged to pass beneath at least one bottom electrode segment in the emission area of an independent OLED segment;
wherein the overlap between the bottom electrode of the independent OLED segment and the power feeds passing beneath the bottom electrode forms an associated passive capacitor structure, where the bottom electrode segment is the upper electrode of the passive capacitor structure, the insulating layer is the dielectric of the passive capacitor structure, and the multiple power feeds together are the lower electrode of the passive capacitor structure.

16. The OLED device of claim 15 where in at least one independent OLED segment, the area of the overlap between the multiple power feeds and the bottom electrode segment in the associated passive capacitor increases the total capacitance of the independent OLED segment by at least 0.2 nF.

17. The OLED device of claim 16 where the total overlap between the sum area of power feeds and the overlying bottom electrode in the associated passive capacitor of the independent OLED segment is 30% or more of the area of the bottom electrode segment.
